(19) United States
(12) Patent Application Publication
(10) Pub. No.: US 2014/0048317 A1
(43) Pub. Date: Feb. 20, 2014

(54) MELTABLE PAINT FILMS AND FABRICS AND METHODS OF MANUFACTURING THEREOF

(71) Applicants: Doron Marco, Tel Aviv (IL); Shany Peled, Netanya (IL); Yariv Ziv, Ra anana (IL); Shlomi Eiger, Tel Aviv (IL); Gad Ben Zvi, Israel (IL); Amiram Finkel, Israel (IL)

(72) Inventors: Doron Marco, Tel Aviv (IL); Shany Peled, Netanya (IL); Yariv Ziv, Ra anana (IL); Shlomi Eiger, Tel Aviv (IL); Gad Ben Zvi, Israel (IL); Amiram Finkel, Israel (IL)

(73) Assignee: WHITE INNOVATION LTD., Tel Aviv (IL)

(21) Appl. No.: 13/984,372

(22) PCT Filed: Feb. 9, 2012
(86) PCT No.: PCT/IL12/00069

§ 371 Date: Oct. 28, 2013

Related U.S. Application Data
(60) Provisional application No. 61/440,960, filed on Feb. 9, 2011.
(60) Provisional application No. 61/568,208, filed on Dec. 8, 2011.

(51) Int. Cl. D04B 1/16; D04H 1/08; H05K 1/03; D03D 25/00

(52) U.S. Cl. CPC D04B 1/16; D03D 25/00; D04H 1/08; H05K 1/038
USPC 174/255; 442/304; 442/181; 442/320; 428/364

(57) ABSTRACT

A fabric which is formed of fibers joined together by at least one of knitting, weaving and felting techniques, which is characterized by having a first non-adhesive solid state and a second adhesive solid state, which occurs subsequent to having passed through an adhesive non-solid state.

### REFERENCE TO RELATED APPLICATIONS

Reference is made to U.S. Provisional Patent Application Ser. No. 61/440,960, filed Feb. 9, 2011 and entitled “MELTABLE FABRICS AND METHODS OF MANUFACTURING THEREOF”, the disclosure of which is hereby incorporated by reference and priority of which is hereby claimed pursuant to 37 CFR 1.78(a) (4) and (5)(i).

Reference is also made to U.S. Provisional Patent Application Ser. No. 61/568,208, filed Dec. 8, 2011 and entitled “MELTABLE PAINT FILM AND METHODS OF MANUFACTURING THEREOF”, the disclosure of which is hereby incorporated by reference and priority of which is hereby claimed pursuant to 37 CFR 1.78(a) (4) and (5)(i).

### FIELD OF THE INVENTION

The present invention relates to meltable paint films and fabrics and methods of manufacturing thereof.

### BACKGROUND OF THE INVENTION

The following patent publications are believed to represent the current state of the art:

U.S. Pat. Nos.: 3,558,412; 4,913,937; 6,479,143 and 6,588,237; and

U.S. Published Patent Application No.: 2006/0016545.

### SUMMARY OF THE INVENTION

The present invention provides meltable paint films and fabrics and methods of manufacturing thereof.

There is thus provided in accordance with a preferred embodiment of the present invention a fabric which is formed of fibers joined together by at least one of knitting, weaving and felting techniques, which is characterized by having a first non-adhesive solid state and a second adhesive solid state, which occurs subsequent to having passed through an adhesive non-solid state.

In accordance with a preferred embodiment of the present invention, the fibers are formed of a material characterized by having the first non-adhesive solid state and the second adhesive solid state, which occurs subsequent to having passed through an adhesive non-solid state. Preferably, the fibers include first and second different fibers which are characterized in that they assume the adhesive non-solid state when they are together subject to predetermined activation conditions. Preferably, the predetermined activation conditions include application of at least one of pressure, heat, ultraviolet radiation, electricity and a solvent. Preferably, the solvent includes petroleum distillate.

Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is also provided in accordance with another preferred embodiment of the present invention a fabric which is formed of fibers joined together by at least one of knitting, weaving and felting techniques, which is characterized by having a first thickness in a first solid state and a second thickness in a second solid state subsequent to having passed through a non-solid state, the second thickness being less than 60% of the first thickness. More preferably, the second thickness is less than 50% of the first thickness. More preferably, the second thickness is less than 40% of the first thickness. More preferably, the second thickness is less than 10% of the first thickness.

Additionally, the fabric is further characterized in having adhesive properties in the second solid state but not in the first solid state. Preferably, the fibers are characterized in that they assume the non-solid state when they are subject to predetermined activation conditions. Preferably, the predetermined activation conditions include application of at least one of pressure, heat, ultraviolet radiation, electricity and a solvent. Preferably, the solvent includes petroleum distillate.

Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is further provided in accordance with yet another preferred embodiment of the present invention a fiber having adhesive properties following activation thereof, including approximately 45% Ethyl vinyl acetate 18% monomer, 30% HDPE and 24% hot melt adhesive pellets including Ethyl vinyl acetate 9% monomer, hydrogenated hydrocarbon tackifier resin and Oil wax, and generally having the following characteristics: a tensile strength of at least 50 RKM, an ultimate elongation of at most 15%, a melting point of less than 80° C., an adherence shear to steel (0.5 kg, min) between 130 and 300, a peel adhesion to steel (N/25 mm) between 10 and 40 and a length per weight between 40 and 50 meters per gram.

Preferably, the activation includes application of at least one of pressure, heat, ultraviolet radiation, electricity and a solvent. Preferably, the solvent includes petroleum distillate. Preferably, the fiber also includes at least one pigment.

There is yet further provided in accordance with still another preferred embodiment of the present invention a fabric which is formed of fibers having adhesive characteristics following activation thereof which are joined by at least one of knitting, weaving and felting.

In accordance with a preferred embodiment of the present invention, the fibers are formed of a material characterized by having the first non-adhesive solid state and the second adhesive solid state, which occurs subsequent to having passed through an adhesive non-solid state. Preferably, the fibers include first and second different fibers which are characterized in that they assume the adhesive non-solid state when they are together subject to predetermined activation conditions. Preferably, the predetermined activation conditions include application of at least one of pressure, heat, ultraviolet radiation, electricity and a solvent. Preferably, the solvent includes petroleum distillate.

Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is yet further provided in accordance with still another preferred embodiment of the present invention a knitted fabric which is formed of at least first and second different fibers having respective first and second different adhesive characteristics and which is characterized by a first surface formed at least principally of the first fibers having the first adhesive characteristics and a second surface formed at least principally of the second fibers having the second adhesive characteristic.

In accordance with a preferred embodiment of the present invention, the knitted fabric is also characterized by having a first non-adhesive solid state and a second solid state, which occurs subsequent to having passed through an adhesive non-solid state. Preferably, the fibers are formed of a material characterized by having the first non-adhesive solid state and the second solid state, which occurs subsequent to having passed through an adhesive non-solid state. Additionally, the fibers assume the adhesive non-solid state when they are subject to predetermined activation conditions.

Preferably, the predetermined activation conditions include application of at least one of pressure, heat, ultraviolet radiation, electricity and a solvent. Preferably, the solvent includes petroleum distillate. Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is also provided in accordance with another preferred embodiment of the present invention a composition including approximately 45% ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the composition also includes at least one pigment.

There is further provided in accordance with yet another preferred embodiment of the present invention a fiber including approximately 45% ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the fiber also includes at least one pigment.

Preferably, the tensile strength of the fiber is at least 10 RKM. More preferably, the tensile strength of the fiber is at least 13.5 RKM. More preferably, the tensile strength of the fiber is at least 50 RKM.

Preferably, the ultimate elongation of the fiber is at most 20%. More preferably, the ultimate elongation of the fiber is between 5% and 20%. More preferably, the ultimate elongation of the fiber is at most 15%.

Preferably, the melting point of the fiber is less than 300° C. More preferably, the melting point of the fiber is between 60° C. and 150° C. More preferably, the melting point of the fiber is less than 80° C.

Preferably, the adherence shear to steel (0.5 kg, min) of the fiber is between 130 and 300. Preferably, the peel adhesion to steel (N/25 mm) of the fiber is between 10 and 40. Preferably, the length per weight of the fiber is between 40 and 50 meters per gram.

Additionally, the fiber also has adhesive properties following activation thereof. Preferably, the activation includes application of at least one of pressure, heat, ultraviolet radiation, electricity and a solvent. Preferably, the solvent includes petroleum distillate.

There is yet further provided in accordance with still another preferred embodiment of the present invention a fabric which is formed of fibers including approximately 45% Ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the fibers also include at least one pigment.

In accordance with a preferred embodiment of the present invention, the fibers are joined together by at least one of knitting, weaving and felting techniques. Preferably, at least some of the fibers include different pigments. Additionally or alternatively, the fabric is characterized by having a first pattern state and a second pattern state, which transformation of the fabric between the pattern states occurs subsequent to application of at least one of heat and electricity. Additionally or alternatively, the fiber also has adhesive properties following activation thereof. Preferably, the activation includes application of at least one of pressure, heat, ultraviolet radiation, electricity and a solvent. Preferably, the solvent includes petroleum distillate.

There is yet further provided in accordance with another preferred embodiment of the present invention a method of manufacturing a fabric including at least one of knitting, weaving and felting of fibers, which are characterized by having a first non-adhesive solid state and a second solid state, which occurs subsequent to having passed through an adhesive non-solid state.

In accordance with a preferred embodiment of the present invention, the fibers are formed of a material characterized by having the first non-adhesive solid state and the second adhesive solid state, which occurs subsequent to having passed through an adhesive non-solid state. Preferably, the fibers include first and second different fibers which are characterized in that they assume the adhesive non-solid state when they are together subject to predetermined activation conditions.

In accordance with a preferred embodiment of the present invention, the predetermined activation conditions include application of at least one of pressure, heat, ultraviolet radiation, electricity and a solvent. Preferably, the solvent includes petroleum distillate. Additionally or alternatively, the fabric also includes an array of electrical conductors which when connected to a source of electrical energy produce the activation of the fabric.

Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is also provided in accordance with another preferred embodiment of the present invention a method of manufacturing a fabric including least one of knitting, weaving and felting of fibers, wherein the at least one of knitting, weaving and felting includes forming interstices covering approximately 50% of the area of the fabric, and which fabric is characterized by having a first thickness in a first solid state and a second thickness in a second solid state subsequent to having passed through a non-solid state, the second thickness being less than 60% of the first thickness. More preferably, the second thickness is less than 50% of the first thickness. More preferably, the second thickness is less than 40% of the first thickness. More preferably, the second thickness is less than 10% of the first thickness.

In accordance with a preferred embodiment of the present invention, the fabric is further characterized in having adhesive properties in the second solid state but not in the first solid state. Preferably, the fibers are characterized in that they assume the non-solid state when they are subject to predetermined activation conditions. Preferably, the predetermined activation conditions include application of at least one of pressure, heat, ultraviolet radiation, electricity and a solvent. Preferably, the solvent includes petroleum distillate.

Additionally or alternatively, the fabric also includes an array of electrical conductors which when connected to a source of electrical energy produce the activation of the fabric. Additionally or alternatively, the fabric also includes acoustic insulating, material joined to the fibers by at least one of interknitting and interweaving. Additionally or alternatively, the fabric also includes thermal insulating material joined to the fibers by at least one of interknitting and interweaving.

There is further provided in accordance with yet another preferred embodiment of the present invention a method of manufacturing a fiber having adhesive properties following activation thereof, the fiber including approximately 45% ethyl vinyl acetate 18% monomer, 30% HDPE and 24% hot melt adhesive pellets including ethyl vinyl acetate 9% monomer, hydrogenated hydrocarbon tackifier resin and oil wax, and generally having the following characteristics: a tensile strength of at least 50 RKM, an ultimate elongation of at most 15%, a melting point of less than 80° C., an adherence shear to steel (0.5 kg, min) between 130 and 300, a peel adhesion to steel (N/25 mm) between 10 and 40, and a length per weight between 40 and 50 meters per gram. Preferably, the method also includes forming a liquid composition and forming the at least one fiber from the liquid composition.

Preferably, the activation includes application of at least one of pressure, heat, ultraviolet radiation, electricity and a solvent. Preferably, the solvent includes petroleum distillate. Preferably, the fiber also includes at least one pigment.

There is yet further provided in accordance with still another preferred embodiment of the present invention a method of manufacturing a fabric including at least one of knitting, weaving and felting of fibers having adhesive characteristics following activation thereof.

In accordance with a preferred embodiment of the present invention, the fibers are formed of a material characterized by having the first non-adhesive solid state and the second adhesive solid state, which occurs subsequent to having passed through an adhesive non-solid state. Additionally, the fibers include first and second different fibers which are characterized in that they assume the adhesive non-solid state when they are together subject to predetermined activation conditions.

Preferably, the predetermined activation conditions include application of at least one of pressure, heat, ultraviolet radiation, electricity and a solvent. Preferably, the solvent includes petroleum distillate. Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is also provided in accordance with another preferred embodiment of the present invention a method of manufacturing a fabric including knitting at least first and second different fibers having respective first and second different adhesive characteristics, forming a first surface at least principally of the first fibers having the first adhesive characteristics and forming a second surface at least principally of the second fibers having the second adhesive characteristics.

In accordance with a preferred embodiment of the present invention, the fabric is also characterized by having a first non-adhesive solid state and a second solid state, which occurs subsequent to having passed through an adhesive non-solid state. Preferably, the fibers are formed of a material characterized by having the first non-adhesive solid state and the second solid state, which occurs subsequent to having passed through an adhesive non-solid state. Preferably, the fibers assume the adhesive non-solid state when they are subject to predetermined activation conditions.

Preferably, the predetermined activation conditions include application of at least one of pressure, heat, ultraviolet radiation, electricity and a solvent. Preferably, the solvent includes petroleum distillate.

Additionally or alternatively, the fabric also includes an array of electrical conductors which when connected to a source of electrical energy produce the activation of the fabric. Additionally or alternatively, the fabric also includes acoustic insulating material joined to the fibers by at least one of interknitting and interweaving. Additionally or alternatively, the fabric also includes thermal insulating material joined to the fibers by at least one of interknitting and interweaving.

There is further provided in accordance with still another preferred embodiment, of the present invention a method of manufacturing a composition including mixing approximately 45% ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the method also includes mixing at least one pigment in the composition.

There is yet further provided in accordance with still another preferred embodiment of the present invention a method of manufacturing a fiber including forming at least one fiber including approximately 45% ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the method also includes mixing at least one pigment in the composition.

Preferably, the tensile strength of the fiber is at least 10 RKM. More preferably, the tensile strength of the fiber is at least 13.5 RKM. More preferably, the tensile strength of the fiber is at least 50 RKM.

Preferably, the ultimate elongation of the fiber is at most 20%. More preferably, the ultimate elongation of the fiber is between 5% and 20%. Most preferably, the ultimate elongation of the fiber is at most 15%.

Preferably, the melting point of the fiber is less than 300° C. More preferably, the melting point of the fiber is between 60° C. and 150° C. Most preferably, the melting point of the fiber is less than 80° C.

Preferably, the adherence shear to steel (0.5 kg, min) of the fiber is between 130 and 300. Preferably, the peel adhesion to steel (N/25 mm) of the fiber is between 10 and 40. Preferably, the length per weight of the fiber is between 40 and 50 meters per gram.

Preferably, the fiber also has adhesive properties following activation thereof. Preferably, the activation includes application of at least one of pressure, heat, ultraviolet radiation, electricity and a solvent. Preferably, the solvent includes petroleum distillate.

There is also provided in accordance with another preferred embodiment of the present invention a method of manufacturing a fabric including at least one of knitting, weaving and felting of fibers, the fibers including approximately 45% Ethyl vinyl acetate 18% monomer, 30% HDPE and 24% hot melt adhesive pellets including ethyl vinyl acetate 9% monomer, hydrogenated hydrocarbon tackifier resin and oil wax. Preferably, the fibers also include at least one pigment.

In accordance with a preferred embodiment of the present invention, the fibers are joined together by at least one of knitting, weaving and felting techniques. Preferably, at least some of the fibers include different pigments. Additionally, the fabric is characterized by having a first pattern state and a second pattern state, which transformation of the fabric between the pattern states occurs subsequent to application of at least one of heat and electricity. Preferably, the fabric also has adhesive properties following activation thereof.

Preferably, the activation includes application of at least one of pressure, heat, ultraviolet radiation, electricity and a solvent. Preferably, the solvent includes petroleum distillate. Preferably, the fibers also include at least one pigment. Additionally, the method also includes forming a liquid composition and forming the at least one fiber from the liquid composition.

There is further provided in accordance with yet another preferred embodiment of the present invention a method of installing a fabric on a surface including locating the fabric while in a first non-adhesive solid state over the surface, activating the fabric, thereby transforming the fabric into an adhesive non-solid state, wherein the fabric is adhered to the surface, and inactivating the fabric, thereby transforming the fabric into a second adhered solid state.

Preferably, the activating includes application of at least one of pressure, heat, ultraviolet radiation, electricity and a solvent. Preferably, the solvent includes petroleum distillate. Additionally or alternatively, the fabric also includes an array of electrical conductors which when connected to a source of electrical energy produce the activation of the fabric.

There is yet further provided in accordance with another preferred embodiment of the present invention a method of manufacturing a product including the steps of forming at least one fiber having a tensile strength of at least 50 RKM, an ultimate elongation of at most 15%, a melting point of less than 80° C., an adherence shear to steel (0.5 kg, min) between 130 and 300, a peel adhesion to steel (N/25 mm) between 10 and 40 and a length per weight between 40 and 50 meters per gram; forming a fabric from the at least one fiber, locating the fabric on a surface and causing the fabric to at least partially enter a non-solid state and thereby to adhere to the surface and thereafter to return to a solid state.

Preferably, the method also includes forming a liquid composition and forming the at least one fiber from the liquid composition. Additionally, the method also includes thereafter causing the fabric to at least partially return to the liquid phase and to disadhere from the surface.

There is also provided in accordance with yet another preferred embodiment of the present invention a meltable paint film which is characterized by having a first semi-adhesive solid state and a second adhesive solid state, which occurs subsequent to the film having passed through a non-solid state.

In accordance with a preferred embodiment of the present invention the meltable paint film is characterized in that it assumes the non-solid state when subject to predetermined activation conditions. Preferably, the predetermined activation conditions include application of at least one of pressure, heat, ultraviolet radiation and a solvent to the film.

Preferably, the meltable paint film also includes a release layer adhered thereto. Preferably, the pressure and the heat are applied to the film by a heated roller via the release layer.

Alternatively, the meltable paint film also includes a polymer coating and a release layer adhered to the polymer coating. Preferably, the pressure and the heat are applied to the film by a heated roller via the release layer and via the polymer coating.

Preferably, the solvent includes petroleum distillate.

Preferably, the film is also characterized by having a first thickness in a first semi-adhesive solid state and a second thickness in a second adhesive solid state subsequent to the film having passed through a non-solid state, the second thickness being less than 60% of the first thickness. Preferably, the second thickness is less than 50% of the first thickness. Yet more preferably, the second thickness is less than 40% of the first thickness. Yet more preferably, the second thickness is less than 10% of the first thickness.

There is further provided in accordance with yet another preferred embodiment of the present invention a film including approximately 45% ethyl vinyl acetate 18% monomer, 30% HDPE and 24% hot melt adhesive pellets including ethyl vinyl acetate 9% monomer, hydrogenated hydrocarbon tackifier resin and oil wax, and generally having the following characteristics: a tensile strength of at least 50 RKM, an ultimate elongation of at most 15%, a melting point of less than 100° C., an adherence shear to steel (0.5 kg, min) between 130 and 300, a peel adhesion to steel (N/25 mm) between 10 and 40 and a length per weight between 40 and 50 meters per gram.

Preferably, the film also includes at least one master batch pigment. Preferably, the film also has semi-adhesive properties. Preferably, the film also has adhesive properties following activation thereof. Preferably, the activation includes application of at least one of pressure, heat, ultraviolet radiation and a solvent to the film.

Preferably, the film also includes a release layer adhered thereto. Preferably, the pressure and the heat are applied to the film by a heated roller via the release layer.

Alternatively, the film also includes a polymer coating and a release layer adhered to the polymer coating. Preferably, the pressure and the heat are applied to the film by a heated roller via the release layer and via the polymer coating.

Preferably, the solvent includes petroleum distillate.

There is yet further provided in accordance with still another preferred embodiment of the present invention a method of manufacturing a meltable paint film including extruding a film which is characterized by having a first semi-adhesive solid state and a second adhesive solid state, which occurs subsequent to the film having passed through a non-solid state.

In accordance with a preferred embodiment of the present invention the film is formed of a material characterized by having the first semi-adhesive solid state and the second adhesive solid state, which occurs subsequent to the film having passed through the non-solid state. Preferably, the meltable paint film is characterized in that it assumes the non-solid state when subject to predetermined activation conditions. Preferably, the predetermined activation conditions include application of at least one of pressure, heat, ultraviolet radiation and a solvent to the film.

Preferably, the method of manufacturing a meltable paint film also includes adhering a release layer thereto. Preferably, the pressure and the heat are applied to the film by a heated roller via the release layer.

Alternatively, the method of manufacturing a meltable paint film also includes forming a polymer coating on the film and adhering a release layer to the polymer coating. Preferably, the pressure and the heat are applied to the film by a heated roller via the release layer and via the polymer coating.

Preferably, the solvent includes petroleum distillate.

Preferably, the film is also characterized by having a first thickness in a first solid state and a second thickness in a second solid state subsequent to the film having passed through a non-solid state, the second thickness being less than 60% of the first thickness. More preferably, the second thickness is less than 50% of the first thickness. Yet more preferably, the second thickness is less than 40% of the first thickness. Yet more preferably, the second thickness is less than 10% of the first thickness.

Preferably, the film is further characterized in having semi-adhesive properties in the first solid state and adhesive properties in the second solid state.

There is further provided in accordance with yet another preferred embodiment of the present invention a method of manufacturing a meltable paint film including approximately 45% ethyl vinyl acetate 18% monomer, 30% HDPE and 24% hot melt adhesive pellets including: ethyl vinyl acetate 9% monomer, hydrogenated hydrocarbon tackifier resin and oil wax, and generally having the following characteristics: a tensile strength of at least 50 RKM, an ultimate elongation of at most 15%, a melting point of less than 100° C., an adherence shear to steel (0.5 kg, min) between 130 and 300, a peel adhesion to steel (N/25 mm) between 10 and 40 and a length per weight between 40 and 50 meters per gram.

Preferably, the film also includes one master batch pigment. Preferably, the film also has semi-adhesive properties. Preferably, the film also has adhesive properties following activation thereof. Preferably, the activation includes application of at least one of pressure, heat, ultraviolet radiation and a solvent to the film.

Preferably, the method of manufacturing a meltable paint film also includes adhering a release layer thereto. Preferably, the pressure and the heat are applied to the film by a heated roller via the release layer.

Alternatively, the method of manufacturing a meltable paint film also includes forming a polymer coating on the film and adhering a release layer to the polymer coating. Preferably, the pressure and the heat are applied to the film by a heated roller via the release layer and via the polymer coating.

Preferably, the solvent includes petroleum distillate.

There is yet further provided in accordance with still another preferred embodiment of the present invention a method of installing a meltable paint film on a surface including temporarily adhering the meltable paint film while in a first semi-adhesive solid state to the surface, activating the film, thereby transforming the film into a non-solid state, wherein the film is adhered to the surface and subsequently deactivating the film, thereby transforming the film into a second adhered solid state.

Preferably, the activating includes application of at least one of pressure, heat, ultraviolet radiation and a solvent to the film.

Preferably, the meltable paint film also includes a release layer adhered thereto. Preferably, the pressure and the heat are applied to the film by a heated roller via the release layer. Preferably, the method also includes removing the release layer subsequent to deactivating the film.

Alternatively, the meltable paint film also includes a polymer coating on the film and a release layer adhered to the polymer coating. Preferably, the pressure and the heat are applied to the film by a heated roller via the release layer and via the polymer coating. Preferably, the method also includes removing the release layer and the polymer coating subsequent to deactivating the film.

Preferably, the solvent includes petroleum distillate. Preferably, the method also includes forming a liquid composition and forming the film from the liquid composition.

There is yet further provided in accordance with still another preferred embodiment of the present invention a method of manufacturing a product including the steps of forming a film having a tensile strength of at least 50 RKM, an ultimate elongation of at most 15%, a melting point of less than 100° C., an adherence shear to steel (0.5 kg, min) between 130 and 300, a peel adhesion to steel (N/25 mm) between 10 and 40 and a length per weight between 40 and 50 meters per gram.

Preferably, the method also includes forming a liquid composition and forming the film from the liquid composition.

There is yet further provided in accordance with still another preferred embodiment of the present invention a film including approximately 30% LDPE 470, 30% master batch pigment, 15% anti block, 10% hot melt adhesive pellets including ethyl vinyl acetate 9% monomer, hydrogenated hydrocarbon tackifier resin and oil wax, 2% paraffin wax and 13% PSA C198 (3M), and generally having the following characteristics: a tensile strength of at least 50 RKM, an ultimate elongation of at most 15%, a melting point of less than 100° C., an adherence shear to steel (0.5 kg, min) between 130 and 300, a peel adhesion to steel (N/25 mm) between 10 and 40 and a length per weight between 40 and 50 meters per gram.

In accordance with a preferred embodiment of the present invention the film also has semi-adhesive properties. Preferably, the film also has adhesive properties following activation thereof. Preferably, the activation includes application of at least one of pressure, heat, ultraviolet radiation and a solvent to the film.

Preferably, the film also includes a release layer adhered thereto. Preferably, the pressure and the heat are applied to the film by a heated roller via the release layer.

Alternatively, the film also includes a polymer coating on the film and a release layer adhered to the polymer coating. Preferably, the pressure and the heat are applied to the film by a heated roller via the release layer and via the polymer coating.

Preferably, the solvent includes petroleum distillate.

There is yet further provided in accordance with still another preferred embodiment of the present invention a method of manufacturing a meltable paint film including approximately 30% LDPE 470, 30% master batch pigment, 15% anti block, 10% hot melt adhesive pellets including ethyl vinyl acetate 9% monomer, hydrogenated hydrocarbon tackifier resin and oil wax, 2% paraffin wax and 13% PSA C198 (3M), and generally having the following characteristics: a tensile strength of at least 50 RKM, an ultimate elongation of at most 15%, a melting point of less than 100° C., an adherence shear to steel (0.5 kg, min) between 130 and 300, a peel adhesion to steel (N/25 mm) between 10 and 40 and a length per weight between 40 and 50 meters per gram.

In accordance with a preferred embodiment of the present invention the film also has semi-adhesive properties. Preferably, the film also has adhesive properties following activation thereof. Preferably, the activation includes application of at least one of pressure, heat, ultraviolet radiation and a solvent to the film.

Preferably, the method of manufacturing a meltable paint film also includes adhering a release layer thereto. Preferably, the pressure and the heat are applied to the film by a heated roller via the release layer.

Alternatively, the method of manufacturing a meltable paint film also includes forming a polymer coating on the film and adhering a release layer to the polymer coating. Preferably, the pressure and the heat are applied to the film by a heated roller via the release layer and via the polymer coating.

Preferably, the solvent includes petroleum distillate.

### BRIEF DESCRIPTION OF THE DRAWINGS

The present invention will be understood and appreciated more fully from the following detailed description, taken in conjunction with the drawings in which:

FIG. 1 is a simplified pictorial illustration of a process for producing fibers for use in producing web material in accordance with a preferred embodiment of the present invention;

FIGS. 2A, 2B, 2C, 2D, 2E, 2F, 2G and 2H are simplified pictorial illustrations of various modes of application of web material in accordance with preferred embodiments of the present invention;

FIGS. 3A, 3B and 3C are simplified pictorial illustrations of additional modes of application of web material in accordance with preferred embodiments of the present invention;

FIGS. 4A, 4B, 4C, 4D, 4E, 4F, 4G, 4H & 4I are simplified pictorial illustrations of various modes of application of a web material in accordance with preferred embodiments of the present invention;

FIG. 5 is a simplified pictorial illustration of application of a web material in accordance with a preferred embodiment of the present invention;

FIGS. 6A and 6B are simplified pictorial illustrations of a process for producing meltable paint film in accordance with another preferred embodiment of the present invention;

FIGS. 7A, 7B, 7C, 7D, 7E, 7F, 7G, 7H and 7I are simplified pictorial illustrations of various modes of application of the meltable paint films of FIGS. 6A & 6B;

FIG. 8 is a simplified pictorial illustrations of a process for producing polymer-coated meltable paint film in accordance with yet another preferred embodiment of the present invention; and

FIGS. 9A and 9B are simplified pictorial illustrations of various modes of application of the polymer-coated meltable paint film of FIG. 8.

### DETAILED DESCRIPTION OF PREFERRED EMBODIMENTS

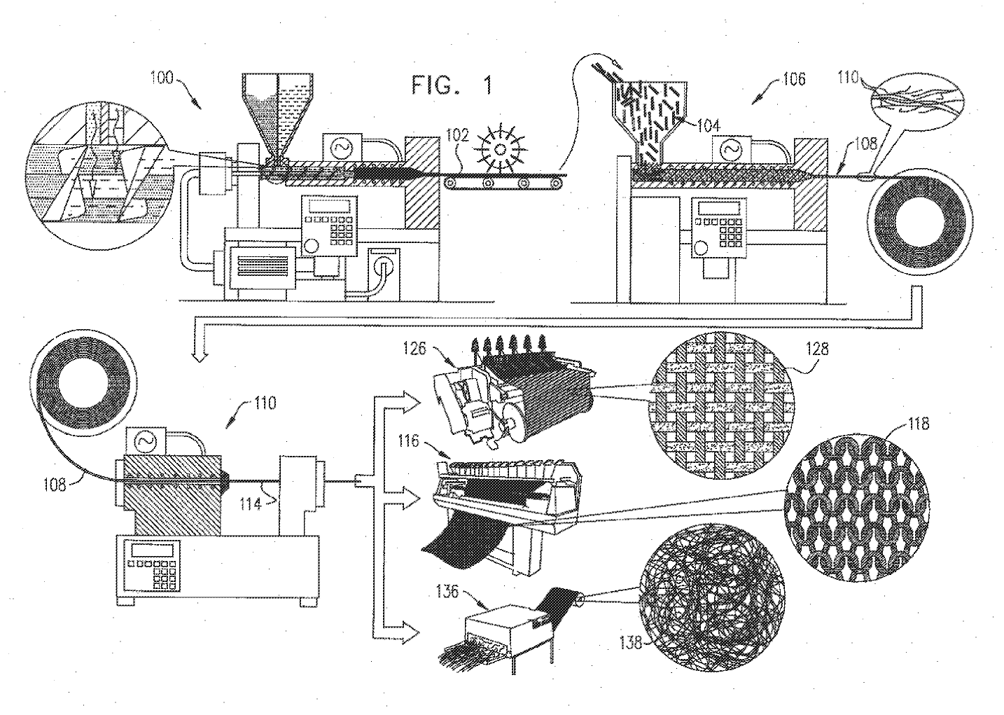

Reference is now made to FIG. 1, which is a simplified pictorial illustration of a process for producing fibers for use in producing web material in accordance with a preferred embodiment of the present invention.

Preferably the fibers are formed of the following composition:
45% Ethyl vinyl acetate 18% monomer;
30% HDPE and
24% hot melt adhesive pellets comprising:

Ethyl vinyl acetate 9% monomer;

Hydrogenated hydrocarbon tackifier resin; and

Oil wax.

Hot melt adhesive pellets of the type specified above are commercially available from Devtec Technological Adhesives Ltd. of Petah Tikva, Israel, under the trade name KOMELT C-190.

Alternatively other suitable fiber compositions may be employed. Additionally, one or more pigments (1%) may be added to the composition to achieve coloring of the resulting fibers.

As seen in FIG. 1, the above ingredients are supplied to a double screw extruder 100, such as a ZPT-HT Series Twin Screw Extruder, commercially available from ZENIX INDUSTRIAL CO. LTD. of Taoyuan, Taiwan, which mixes the above ingredients and extrudes a length of fiber precursor material 102. The fiber precursor material 102 is preferably pelletized downstream of the extruder and pellets 104 of fiber precursor material 102 are supplied to a single screw extruder 106, such as a ZPT-HT Series Twin Screw Extruder, commercially available from ZENIX INDUSTRIAL CO. LTD. of Taoyuan, Taiwan, which extrudes a fiber 108 in accordance with a preferred embodiment of the present invention.

An enlargement of a cross section of fiber 108 indicates that the fiber is formed of a multiplicity of sub-fibers 110 bundled together, each typically of diameter 0.1-0.5 mm. Fiber 108 is supplied to a tensioning device 112, such as a Machine Direction Orientation (MDO) System, commercially available from Parkinson Technologies, Inc. of Woonsocket, R.I., which preferably stretches the fiber by 400%, producing a stretched fiber 114.

The fibers 114 are preferably characterized in that they have both a tensile strength of at least 10 RKM and more preferably of at least 13.5 RKM and most preferably of at least 50 RKM, as well as an ultimate elongation of at most 20%, more preferably between 5% and 20% and most preferably at most 15%, a melting point preferably below 300° C. and more preferably between 60° C. and 150° C. and most preferably about 80° C., adherence shear to steel (0.5 kg, min) of 130-300, and peel adhesion to steel (N/25 mm) of 10-40.

In accordance with a preferred embodiment of the present invention, fibers 114 are supplied to a conventional knitting machine 116, such as a YC-122E/132E knitting machine commercially available from Suzhou Kelian Precision Machinery Co. Ltd. of Jiangsu, China, or an MC-610 Flat Textile Knitting Machine commercially available from Wisconsin Knitwear, Inc. of Milwaukee, Wis., which produces a knitted web material, or knitted fabric 118.

Additionally or alternatively, fibers 114 are supplied to a conventional weaving machine 126, such as an Air Jet Weaving machine commercially available from Nantong Weijian Industry Development Co., Ltd. of Jiangsu, China, or an Automatic multi-function Shuttleless weaving machine commercially available from Anping County Precision Machinery Wire Mesh Factory of Hebei, China, which produces a woven web material, or woven fabric 128.

Additionally or alternatively, fibers 114 are supplied to a conventional felting fabric machine 136, such as an Automatic Non Woven Fabrics Spunbonded Machine (QL1600) commercially available from Ruian Shunfeng Packaging Machinery Co. Ltd. of Zhejiang Ruian, China, which produces a woven web material, or felt fabric 138.

It is a particular feature of the present invention that fibers 114 are suitable for use with conventional knitting, weaving and felting fabric machines 116, 126 and 136.

If the resulting web material is formed of a colored fiber, the fabric constitutes a paint fabric and/or an adhesive fabric.

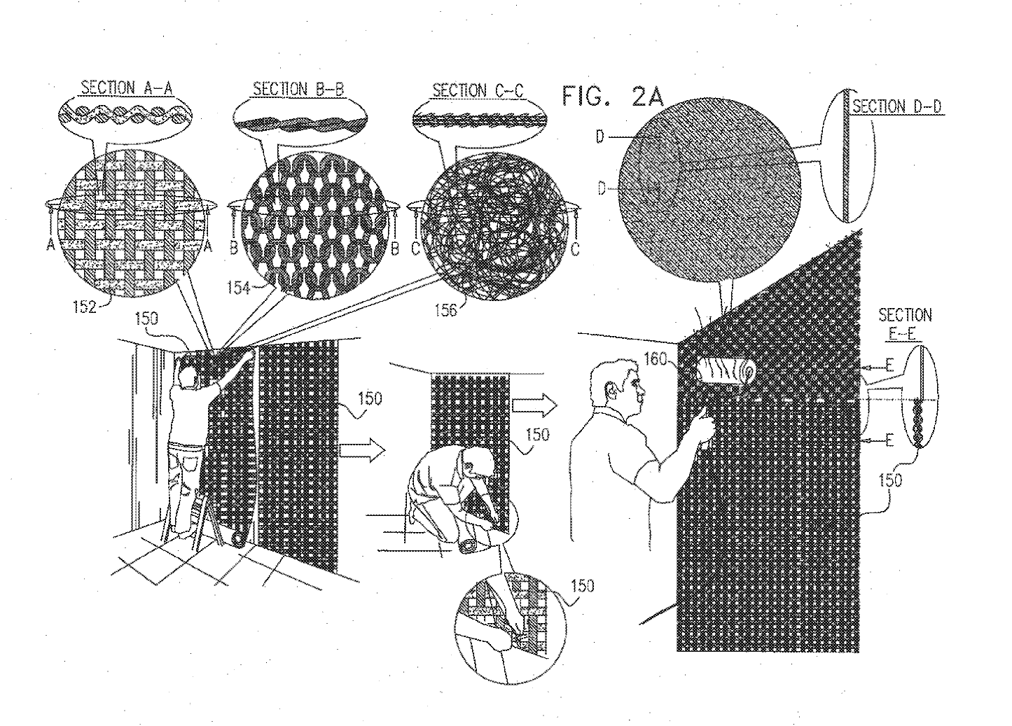

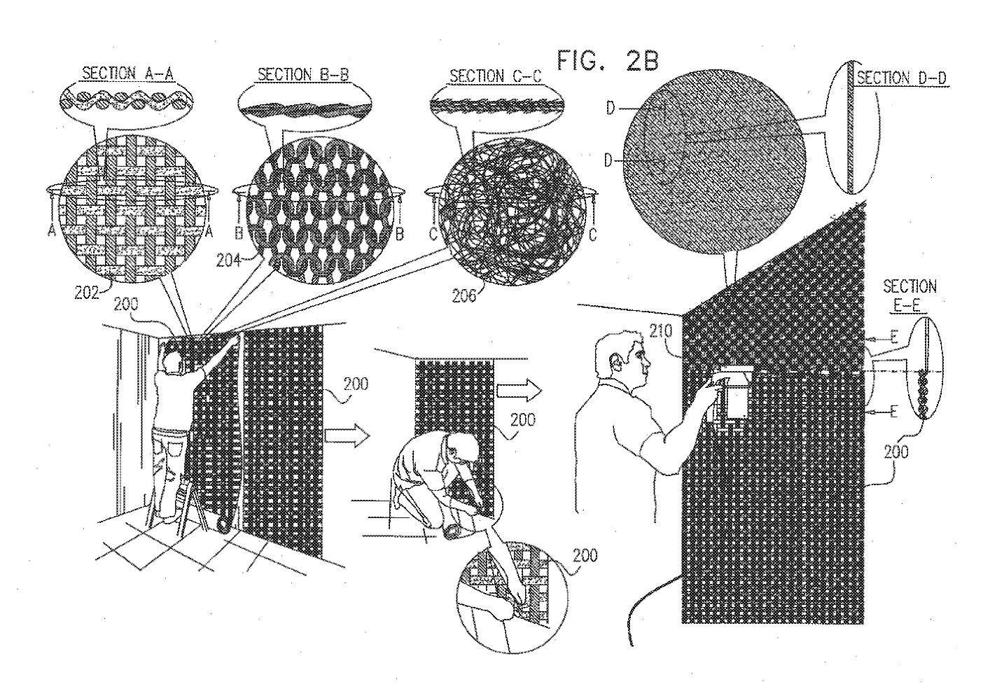

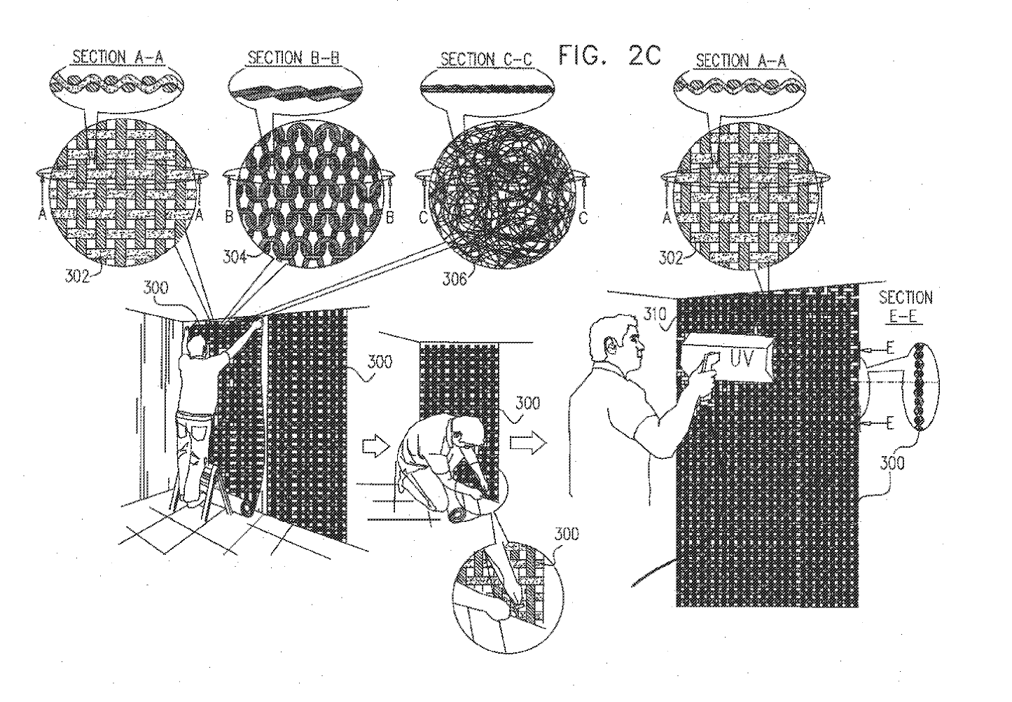

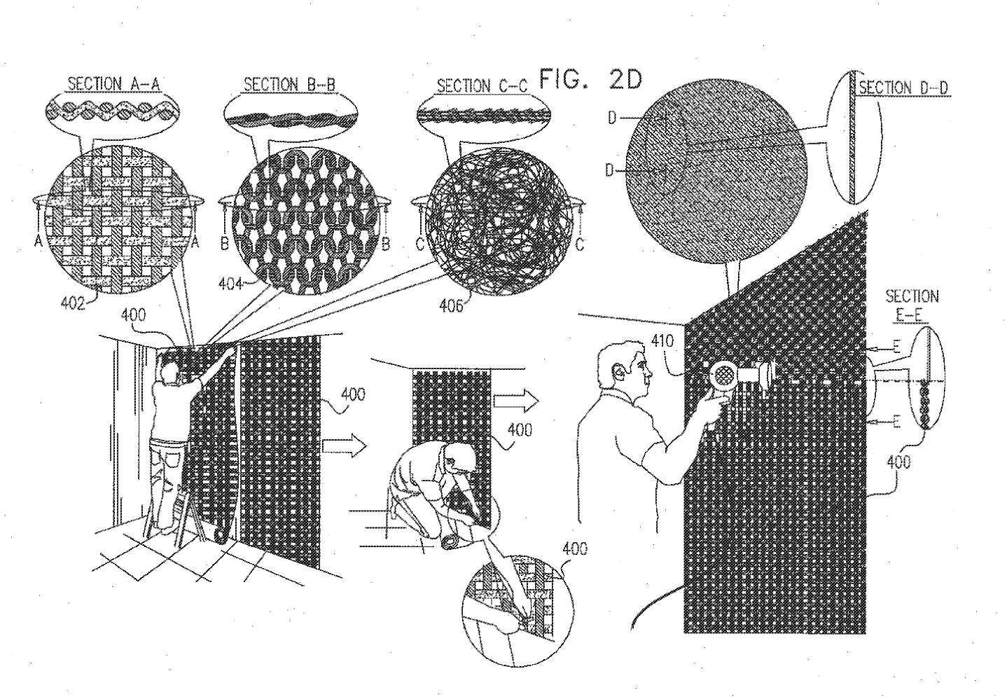

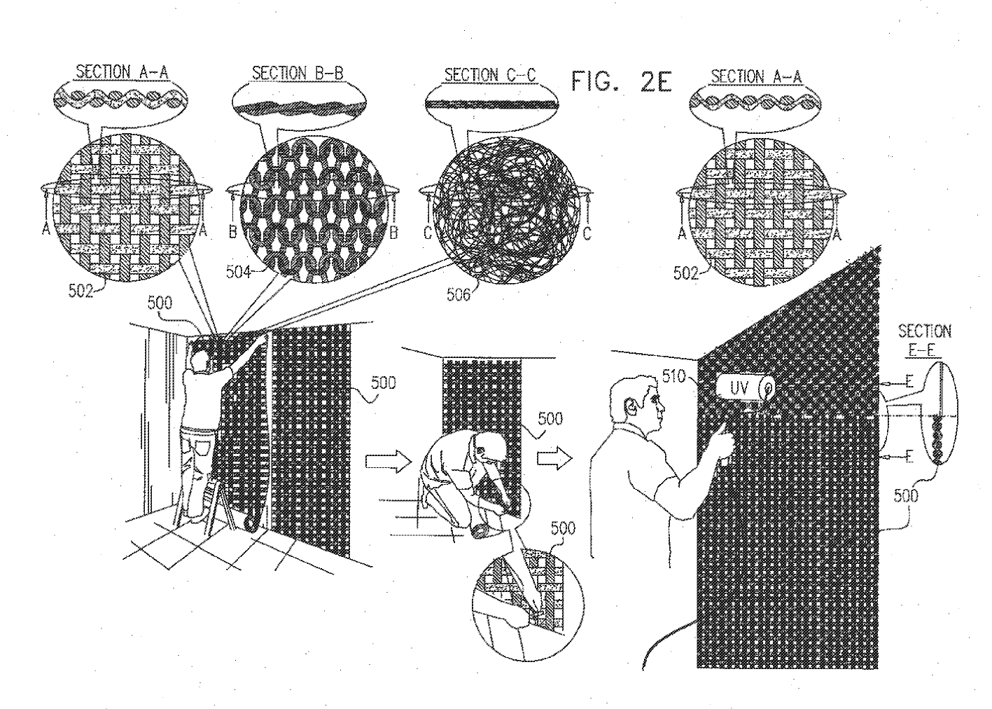

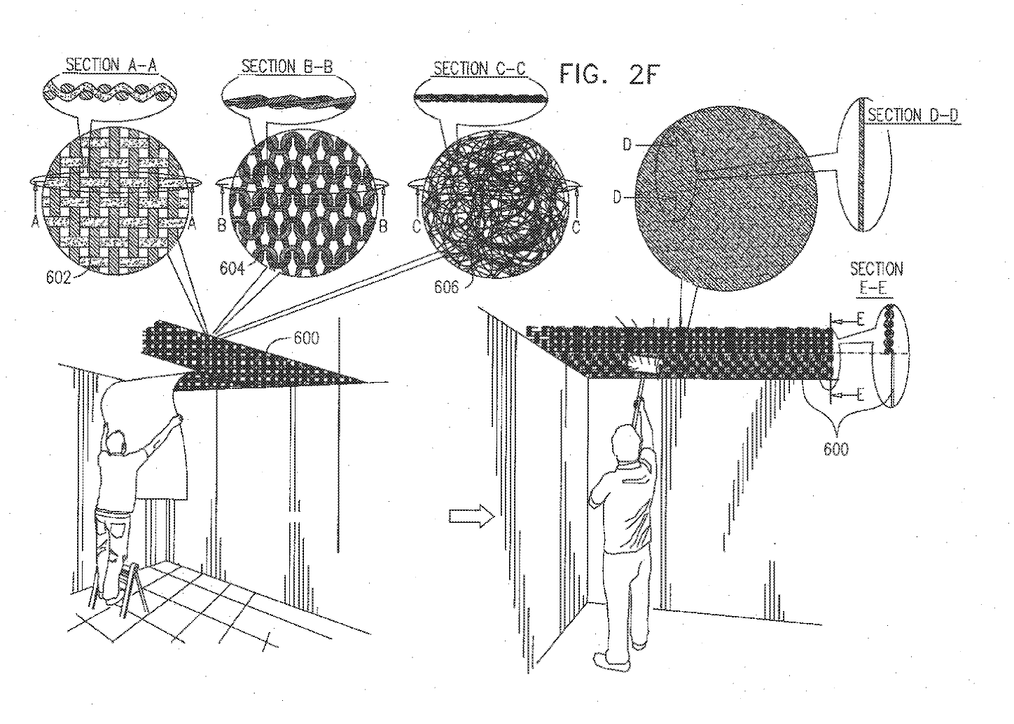

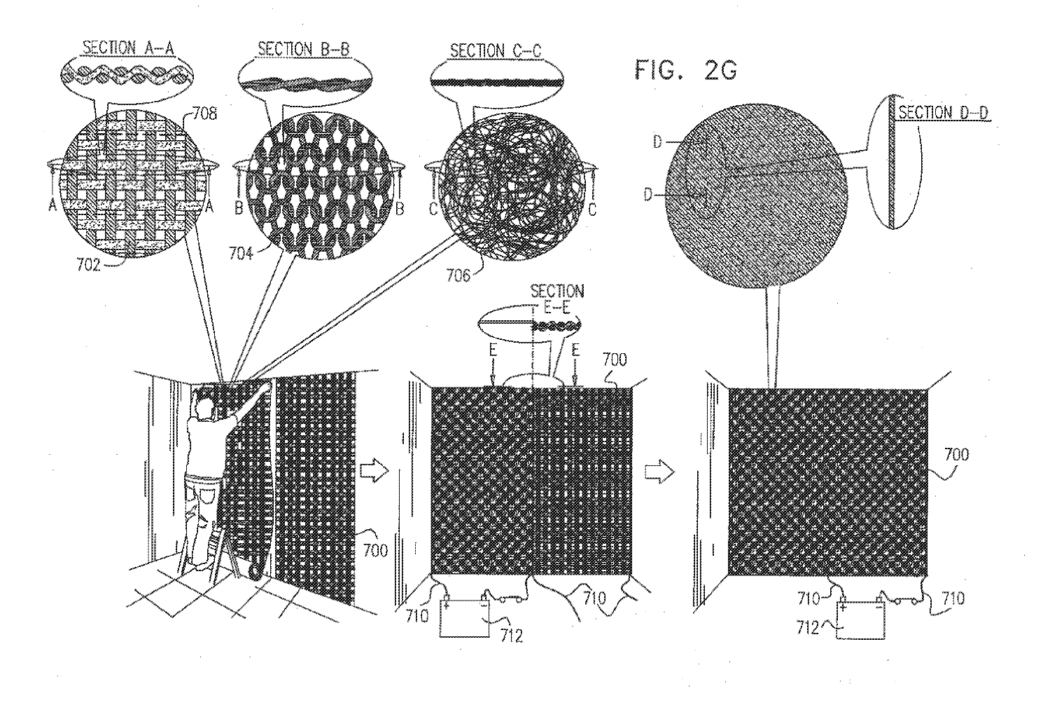

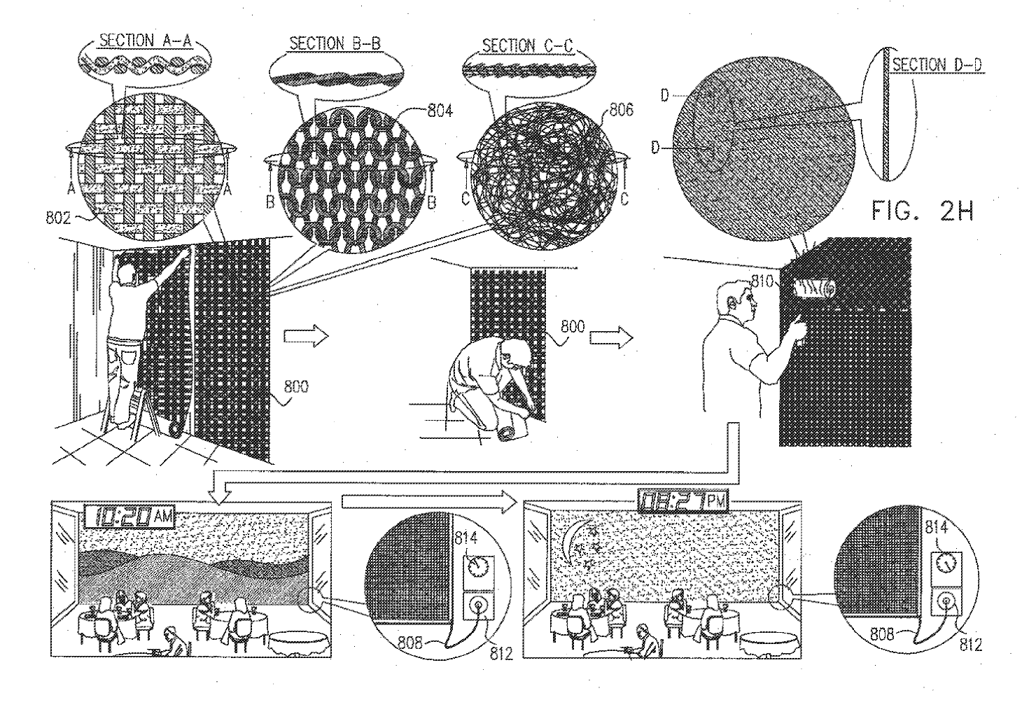

Reference is now made to FIGS. 2A, 2B, 2C, 2D, 2E, 2F, 2G and 2H, which are simplified pictorial illustrations of various modes of application of web material in accordance with preferred embodiments of the present invention. All of FIGS. 2A-2H relate to applications of a coating fabric which is one type of web material constructed and operative in accordance with a preferred embodiment of the present invention.

Referring now specifically to FIG. 2A, there is shown application of a coating fabric 150, which may be, for example, a woven coating fabric 152, formed of warp and woof fibers or yarns of the same or different materials and/or colors, at least some of which, and preferably all of which, are coating fibers or coating yarns.

Another example of a coating fabric is a knitted coating fabric 154, formed of fibers or yarns of the same or different materials and/or colors, at least some of which, and preferably all of which, are coating fibers or coating yarns. It is appreciated that knitted coating fabric 154 may include additional fibers or yarns which are not knitted.

A further example of a coating fabric is a felt coating fabric 156, formed of fibers or yarns of the same or different materials and/or colors, at least some of which, and preferably all of which, are coating fibers or coating yarns.

Normally, the coating fabric 150 has a thickness of approximately 2 mm, and more preferably 0.5 mm and most preferably 0.05 mm and has interstices whose area covers approximately 50% and more preferably 40% and most preferably 20% of its area.

As seen in FIG. 2A, strips of coating fabric 150 are temporarily hung on a wall surface and cut to fit, and thereafter the coating fabric 150 is heated on the wall surface as by a heated roller 160. Preferably, the temperature of the coating fabric 150 is raised to 300 degrees ° C., more preferably to 100° C. and most preferably to 80° C.

As illustrated in FIG. 2A, heating of the coating fabric 150 on the wall surface causes melting of the coating fabric 150 and adherence thereof to the wall surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 150 prior to and following heating thereof.

Referring now specifically to FIG. 2B, there is shown application of a coating fabric 200, which may be, for example, a woven coating fabric 202, as described above, a knitted coating fabric 204, as described above or a felt coating fabric 206, as described hereinabove.

Normally, the coating fabric 200 has a thickness of approximately 2 mm, and more preferably 0.5 mm and most preferably 0.05 mm and has interstices whose area covers approximately 50% and more preferably 40% and most preferably 20% of its area.

As seen in FIG. 2B, strips of coating fabric 200 are temporarily hung on a wall surface and cut to fit, and thereafter the coating fabric 200 is caused to assume a liquid-like phase on the wall surface as application thereto of a suitable solvent, such as petroleum distillate.

As illustrated in FIG. 2B, the resulting dissolving of the coating fabric 200 on the wall surface causes adherence of the dissolved coating fabric to the wall surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 200 prior to and following application of solvent thereto.

Referring now specifically to FIG. 2C, there is shown application of a coating fabric 300, which may be, for example, a woven coating fabric 302, as described above, a knitted coating fabric 304, as described above or a felt coating fabric 306, as described hereinabove.

Normally, the coating fabric 300 has a thickness of approximately 2 mm, and more preferably 0.5 mm and most preferably 0.05 mm and has interstices whose area covers approximately 50% and more preferably 40% and most preferably 20% of its area.

As seen in FIG. 2C, strips of coating fabric 300 are temporarily hung on a wall surface and cut to fit, and thereafter the coating fabric 300 is treated by UV radiation to adhere to the wall surface and optionally to change its coloring. The UV radiation is preferably of a wavelength of 300-400 nm and provides 2 Watts of radiation per square centimeter.

As illustrated in FIG. 2C, the UV treatment of the coating fabric 300 on the wall surface causes adherence of the coating fabric to the wall surface, such that the coating yarns or coating fibers do not fully coalesce into an uninterrupted coating and preferably having a thickness which is approximately the same as its earlier thickness. This is illustrated with clarity at section E, which shows the lack of difference in thickness in the coating fabric 300 prior to and following application of UV radiation thereto.

Referring now specifically to FIG. 2D, there is shown application of a coating fabric 400, which may be, for example, a woven coating fabric 402 as described above a knitted coating fabric 404, as described above or a felt coating fabric 406, as described hereinabove.

As seen in FIG. 2D, strips of coating fabric 400 are temporarily hung on a wall surface and cut to fit, and thereafter the coating fabric 400 is heated on the wall surface in a non-contact manner as by a blow heater 410. Preferably, the temperature of the coating fabric 400 is raised to 300 degrees ° C., more preferably to 100° C. and most preferably to 80° C.

As illustrated in FIG. 2D, heating of the coating fabric 400 on the wall surface causes melting of the coating fabric 400 and adherence thereof to the wall surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 400 prior to and following heating thereof.

Referring now specifically to FIG. 2E, there is shown application of a coating fabric 500, which may be, for example, a woven coating fabric 502, as described above, a knitted coating fabric 504, as described above or a felt coating fabric 506, as described hereinabove.

Normally, the coating fabric 500 has a thickness of approximately 2 mm, and more preferably 0.5 mm and most preferably 0.05 mm and has interstices whose area covers approximately 50% and more preferably 40% and most preferably 20% of its area.

As seen in FIG. 2E, strips of coating fabric 500 are temporarily hung on a wall surface and cut to fit and thereafter the coating fabric 500 is treated by UV radiation and pressure, as by a UV roller 510, to adhere to the wall surface and optionally to change its coloring. The UV radiation is preferably of a wavelength of 300-400 nm and provides 2 Watts of radiation per square centimeter.

As illustrated in FIG. 2E, the UV and pressure treatment of the coating fabric 500 on the wall surface causes adherence of the coating fabric to the wall surface, such that the coating yarns or coating fibers do not fully coalesce into an uninterrupted coating and preferably having a thickness which is somewhat less than its earlier thickness. This is illustrated with clarity at section E, which shows the difference in thickness in the coating fabric 500 prior to and following application of UV radiation thereto.

Referring now specifically to FIG. 2F, there is shown application of a coating fabric 600, which may be, for example, a woven coating fabric 602 as described above a knitted coating fabric 604, as described above or a felt coating fabric 606, as described hereinabove.

As seen in FIG. 2F, strips of coating fabric 600 are temporarily hung on a ceiling surface and thereafter the coating fabric 600 is heated on the ceiling surface in a non-contact manner as by heated roller 610. Preferably, the temperature of the coating fabric 600 is raised to 300 degrees ° C., more preferably to 100° C. and most preferably to 80° C.

As illustrated in FIG. 2F, heating of the coating fabric 600 on the ceiling surface causes melting of the coating fabric 600 and adherence thereof to the ceiling surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 600 prior to and following heating thereof.

Referring now specifically to FIG. 2G, there is shown application of a coating fabric 700, which may be, for example, a woven coating fabric 702, formed of warp and woof fibers or yarns of the same or different materials and/or colors, at least some of which, and preferably all of which, are coating fibers or coating yarns.

Another example of a coating fabric is a knitted coating fabric 704, formed of fibers or yarns of the same or different materials and/or colors, at least some of which, and preferably all of which, are coating fibers or coating yarns. It is appreciated that knitted coating fabric 704 may include additional fibers or yarns which are not knitted.

A further example of a coating fabric is a felt coating fabric 706, formed of fibers or yarns of the same or different materials and/or colors, at least some of which, and preferably all of which, are coating fibers or coating yarns.

Coating fabric 700 is particularly characterized in that it includes an array of electrical conductors 708, which preferably extend side to side with respect to the length of a strip of fabric 700. Preferably, side to side extending electrical conductors 708 are interconnected in a parallel arrangement with elongate conductors 710 extending along both edges of the strip of fabric 700.

Normally, the coating fabric 700 has a thickness of approximately 2 mm, and more preferably 0.5 mm and most preferably 0.05 mm and has interstices whose area covers approximately 50% and more preferably 40% and most preferably 20% of its area.

As seen in FIG. 2G, strips of coating fabric 700 are temporarily hung on a wall surface and cut to fit and thereafter the electrical conductors 710 are connected to a source of electrical energy 712 for producing heating thereof and consequent heating of the coating fabric 700 on the wall surface. Preferably, the temperature of the coating fabric 700 is raised to 300 degrees ° C., more preferably to 100° C. and most preferably to 80° C.

As illustrated in FIG. 2G, heating of the coating fabric 700 on the wall surface causes melting of the coating fabric 700 and adherence thereof to the wall surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 700 prior to and following heating thereof.

Subsequent to heating of the coating fabric 700, the source of electrical energy 712 may be disconnected.

Referring now specifically to FIG. 2H, there is shown application of a coating fabric 800, which may be, for example, a woven coating fabric 802, formed of warp and woof fibers or yarns of the same or different materials and/or colors, at least some of which, and preferably all of which are coating fibers or coating yarns.

Another example of a coating fabric is a knitted coating fabric 804, formed of fibers or yarns of the same or different materials and/or colors, at least some of which, and preferably all of which are coating fibers or coating yarns. It is appreciated that knitted coating fabric 804 may include additional fibers or yarns which are not knitted.

A further example of a coating fabric is a felt coating fabric 806, formed of fibers or yarns of the same or different materials and/or colors, at least some of which, and preferably all of which are coating fibers or coating yarns.

Coating fabric 800 is particularly characterized in that it constitutes a selectably actuable display which includes a plurality of selectably colored display elements, each of which is separately electrically actuatable by electrical conductors 808 incorporated in the coating fabric.

As seen in FIG. 2H, strips of coating fabric 800 are temporarily hung on a wall surface and cut to fit and adhered to the wall surface by the application of one or more of heat, UV, solvent and pressure, such as by heat roller 810. The electrical conductors 808 are connected to a source of electrical energy 812 via a pattern actuation switch mechanism 814 for selectably producing a desired display pattern thereby, as by reversible thermochromic changes in the fabric resulting from selected heating of electrical conductors 808, as governed by pattern actuation switch mechanism 814.

Different patterns may be displayed at will, for example, as seen at enlargement A, the wall of a restaurant may show a day scene during the day and as seen at enlargement B, a night scene at night.

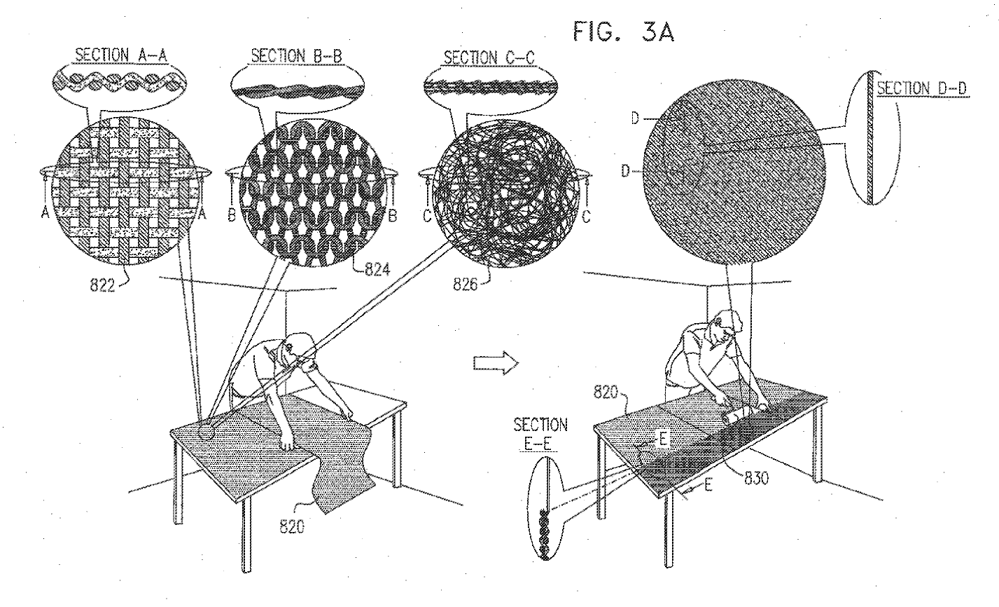

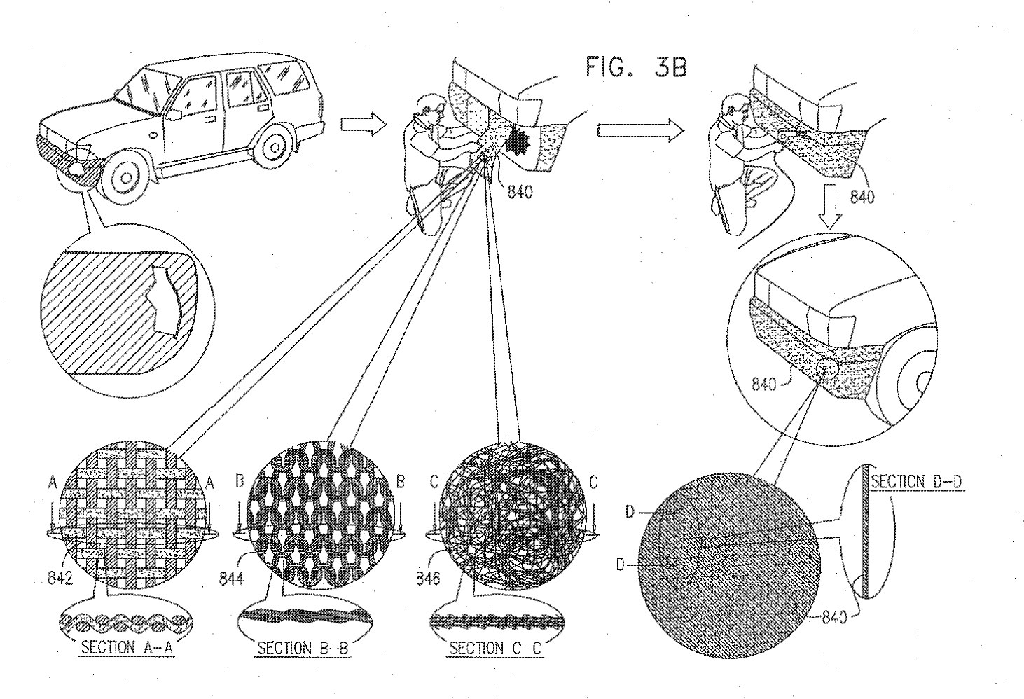

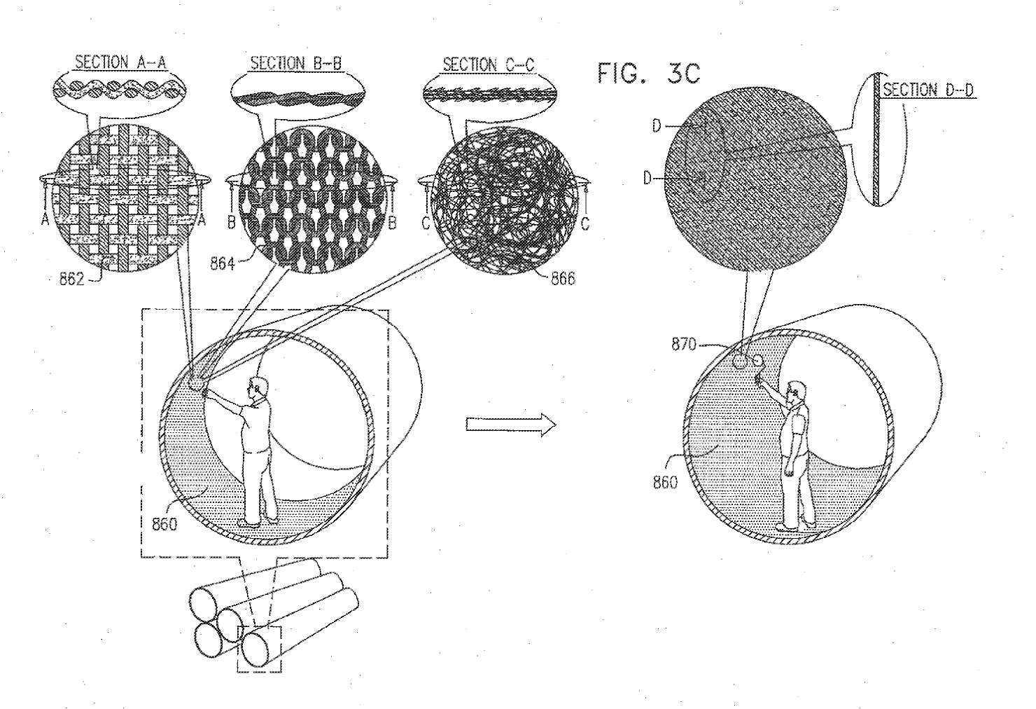

Reference is now made to FIGS. 3A, 3B and 3C, which are simplified pictorial illustrations of additional modes of application of a coating fabric in accordance with preferred embodiments of the present invention.

Referring now specifically to FIG. 3A, there is shown application of a coating fabric 820, which may be, for example, a woven coating fabric 822, formed of warp and woof fibers or yarns of the same or different materials and/or colors, at least some of which, and preferably all of which, are coating fibers or coating yarns.

Another example of a coating fabric is a knitted coating fabric 824, formed of fibers or yarns of the same or different materials and/or colors, at least some of which, and preferably all of which, are coating fibers or coating yarns. It is appreciated that knitted coating fabric 824 may include additional fibers or yarns which are not knitted.

A further example of a coating fabric is a felt coating fabric 826, formed of fibers or yarns of the same or different materials and/or colors, at least some of which, and preferably all of which, are coating fibers or coating yarns.

Normally, the coating fabric 820 has a thickness of approximately 2 mm, and more preferably 0.5 mm and most preferably 0.05 mm and has interstices whose area covers approximately 50% and more preferably 40% and most preferably 20% of its area.

As seen in FIG. 3A, strips of coating fabric 820 are placed on a horizontal furniture surface such as a table and cut to fit. Thereafter the coating fabric 820 is heated on the horizontal furniture surface as by a heated roller 830. Preferably, the temperature of the coating fabric 820 is raised to 300 degrees ° C., more preferably to 100° C. and most preferably to 80° C.

As illustrated in FIG. 3A, heating of the coating fabric 820 on the horizontal furniture surface causes melting of the coating fabric 820 and adherence thereof to the horizontal furniture surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness. This is illustrated with clarity at section E, which shows the difference in thickness in the coating fabric 820 prior to and following heating thereof.

Referring now specifically to FIG. 3B, there is shown application of a coating fabric 840, which may be, for example, a woven coating fabric 842, formed of warp and woof fibers or yarns of the same or different materials and/or colors, at least some of which, and preferably all of which, are coating fibers or coating yarns.

Another example of a coating fabric is a knitted coating fabric 844, formed of fibers or yarns of the same or different materials and/or colors, at least some of which, and preferably all of which, are coating fibers or coating yarns. It is appreciated that knitted coating fabric 844 may include additional fibers or yarns which are not knitted.

A further example of a coating fabric is a felt coating fabric 846, formed of fibers or yarns of the same or different materials and/or colors, at least some of which, and preferably all of which, are coating fibers or coating yarns.

Normally, the coating fabric 840 has a thickness of approximately 2 mm, and more preferably 0.5 mm and most preferably 0.05 mm and has interstices whose area covers approximately 50% and more preferably 40% and most preferably 20% of its area.

As seen in FIG. 3B, strips of coating fabric 840 are temporarily hung over a damaged auto body part and cut to fit. Thereafter the coating fabric 840 is heated on the damaged auto body part in a non-contact manner as by a blow heater 850. Preferably, the temperature of the coating fabric 840 is raised to 300 degrees ° C., more preferably to 100° C. and most preferably to 80° C.

As illustrated in FIG. 3B, heating of the coating fabric 840 on the damaged auto body part causes melting of the coating fabric 840 and adherence thereof to the damaged auto body part, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness.

Referring now specifically to FIG. 3C, there is shown application of a coating fabric 860, which may be, for example, a woven coating fabric 862, formed of warp and woof fibers or yarns of the same or different materials and/or colors, at least some of which, and preferably all of which, are coating fibers or coating yarns.

Another example of a coating fabric is a knitted coating fabric 864, formed of fibers or yarns of the same or different materials and/or colors, at least some of which, and preferably all of which, are coating fibers or coating yarns. It is appreciated that knitted coating fabric 864 may include additional fibers or yarns which are not knitted.

A further example of a coating fabric is a felt coating fabric 866, formed of fibers or yarns of the same or different materials and/or colors, at least some of which, and preferably all of which, are coating fibers or coating yarns.

Normally, the coating fabric 860 has a thickness of approximately 2 mm, and more preferably 0.5 mm and most preferably 0.05 mm and has interstices whose area covers approximately 50% and more preferably 40% and most preferably 20% of its area.

As seen in FIG. 3C, strips of coating fabric 860 are temporarily hung on an interior surface of a horizontal pipe and cut to fit. Thereafter the coating fabric 860 is heated on the surface as by a heated roller 870. Preferably, the temperature of the coating fabric 860 is raised to 300 degrees ° C., more preferably to 100° C. and most preferably to 80° C.

As illustrated in FIG. 3C, heating of the coating fabric 860 on the interior surface of the horizontal pipe causes melting of the coating fabric 860 and adherence thereof to the surface, such that the coating yarns or coating fibers coalesce into an uninterrupted coating, preferably not having any interstices and preferably having a thickness which is less than 60% of its earlier thickness and more preferably less than 50% of its earlier thickness and most preferably less than 40% of its earlier thickness.

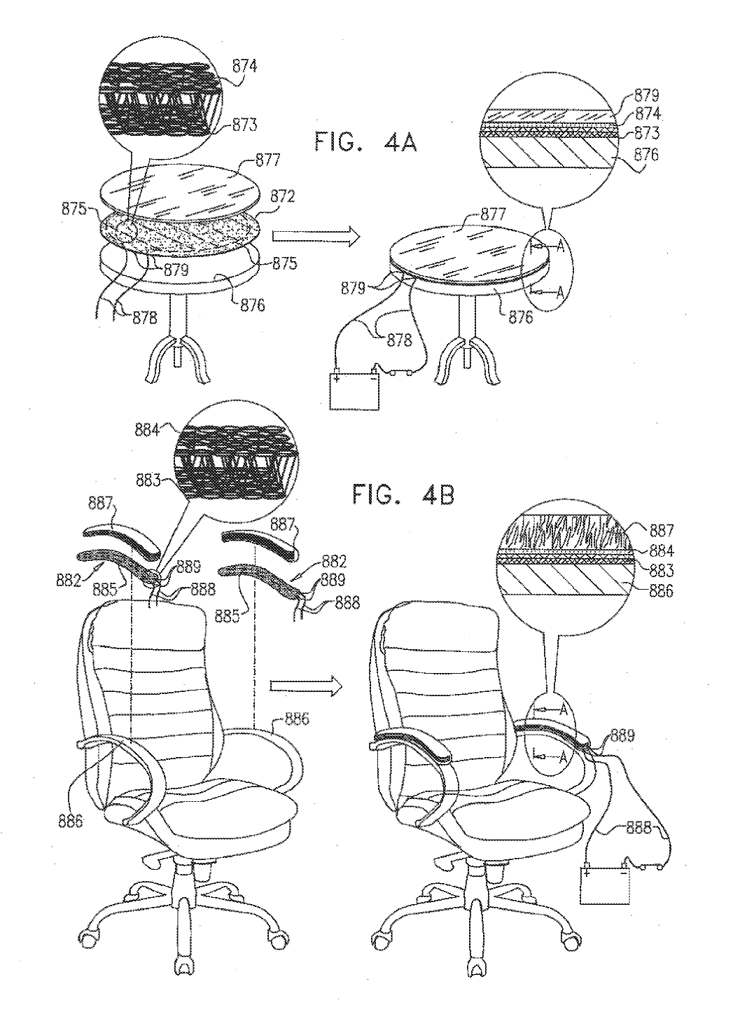

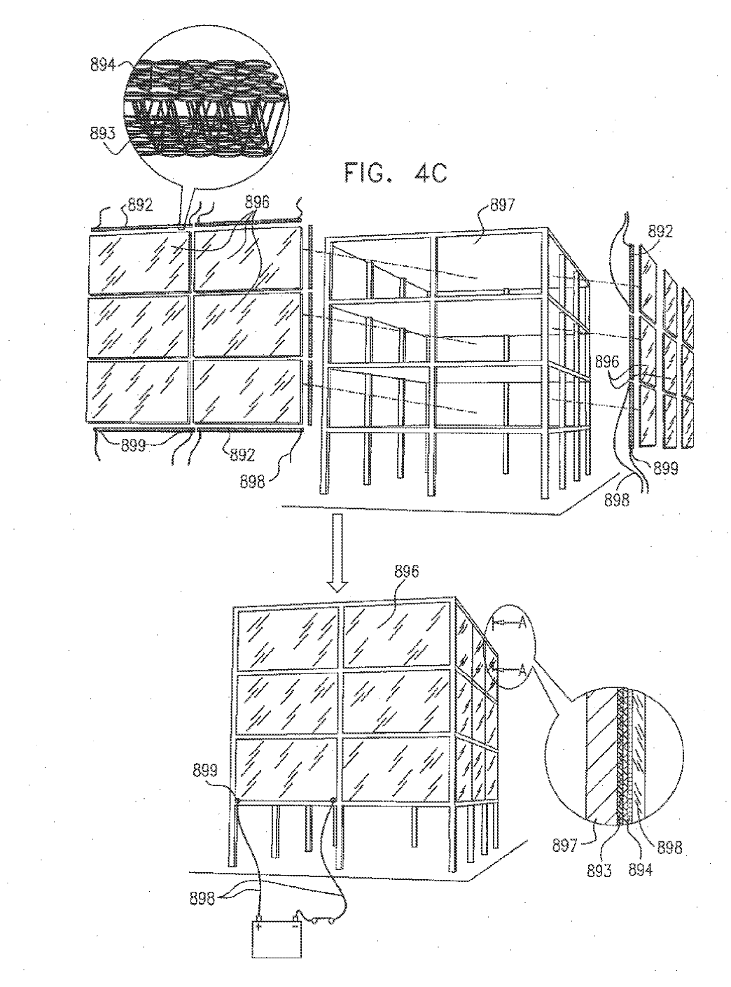

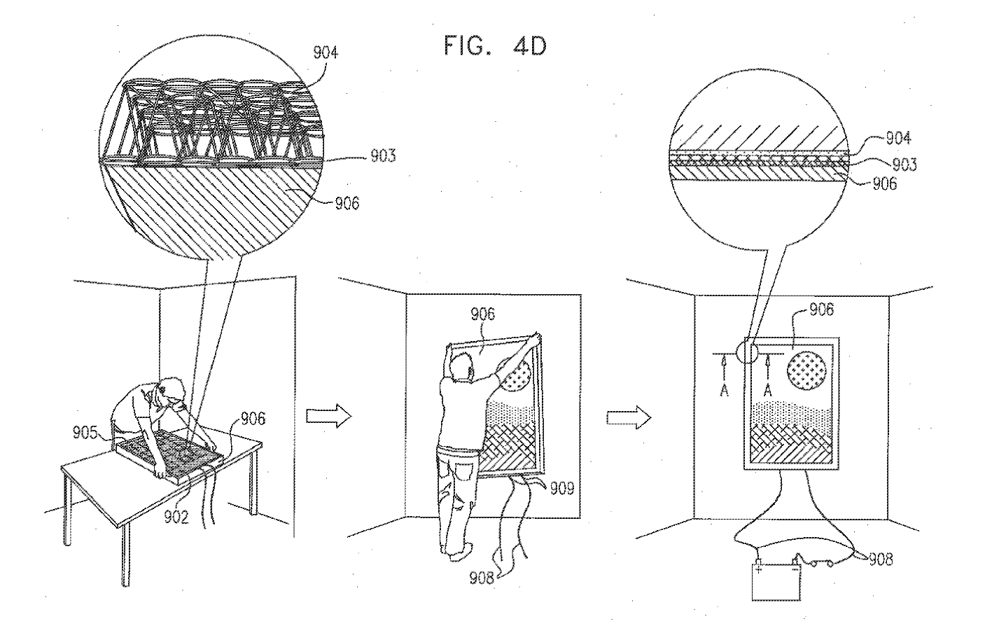

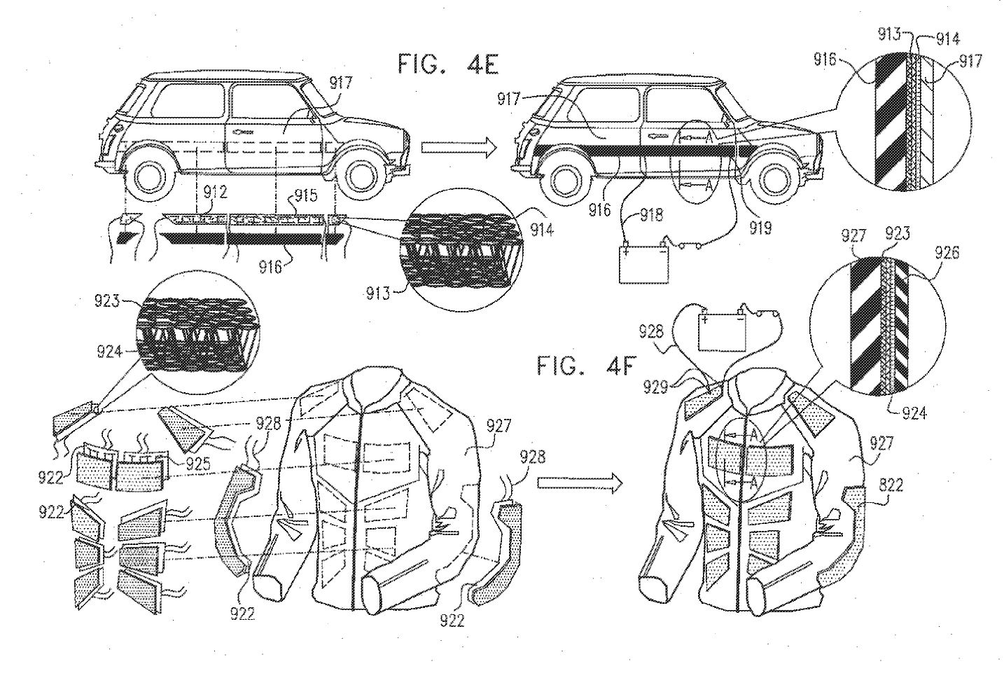

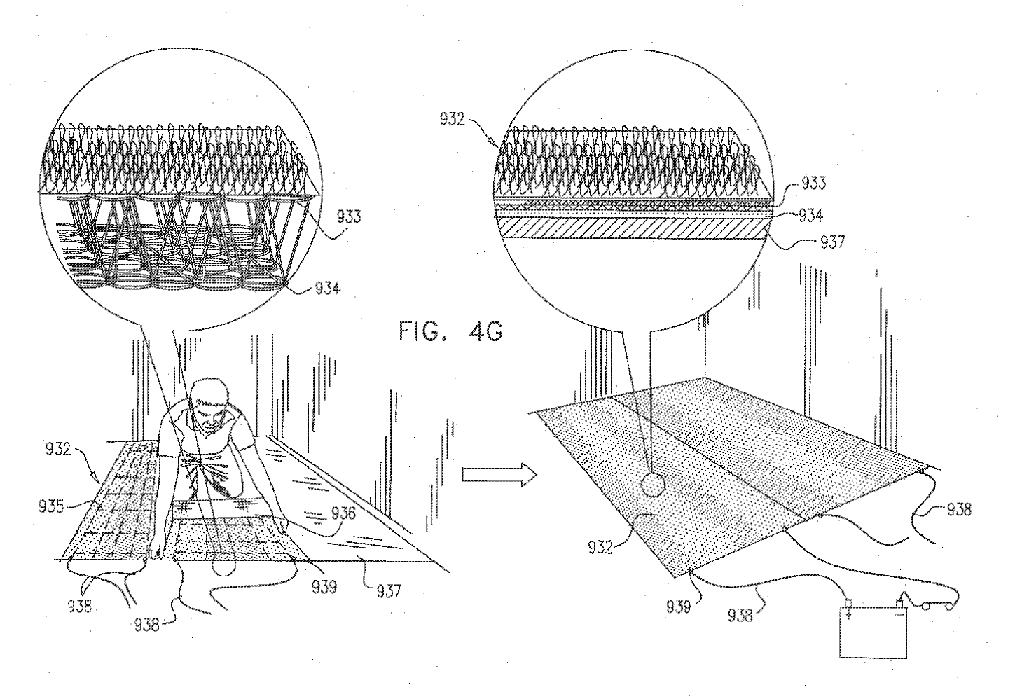

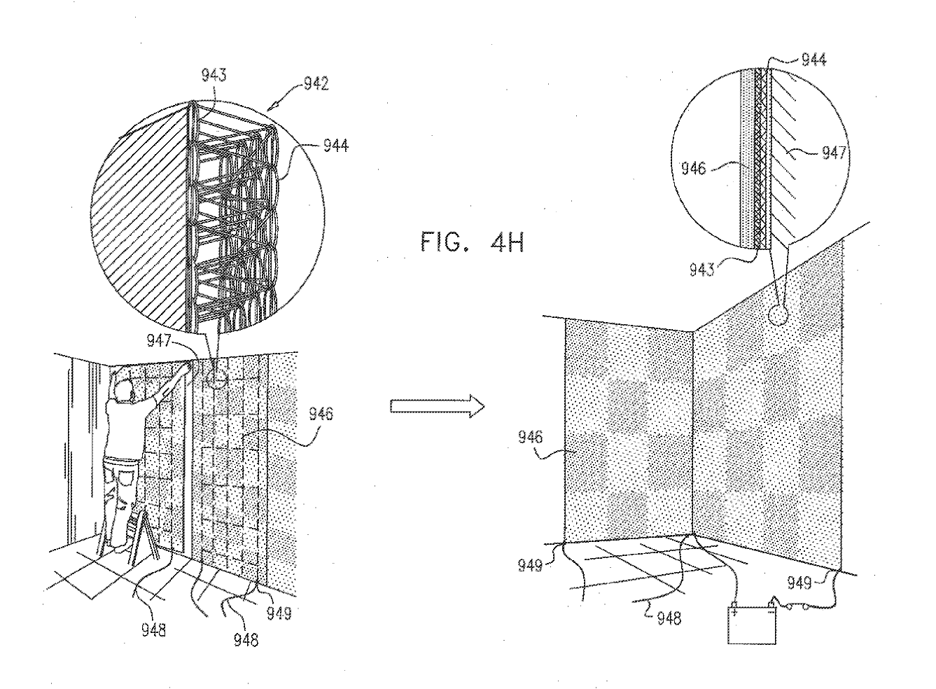

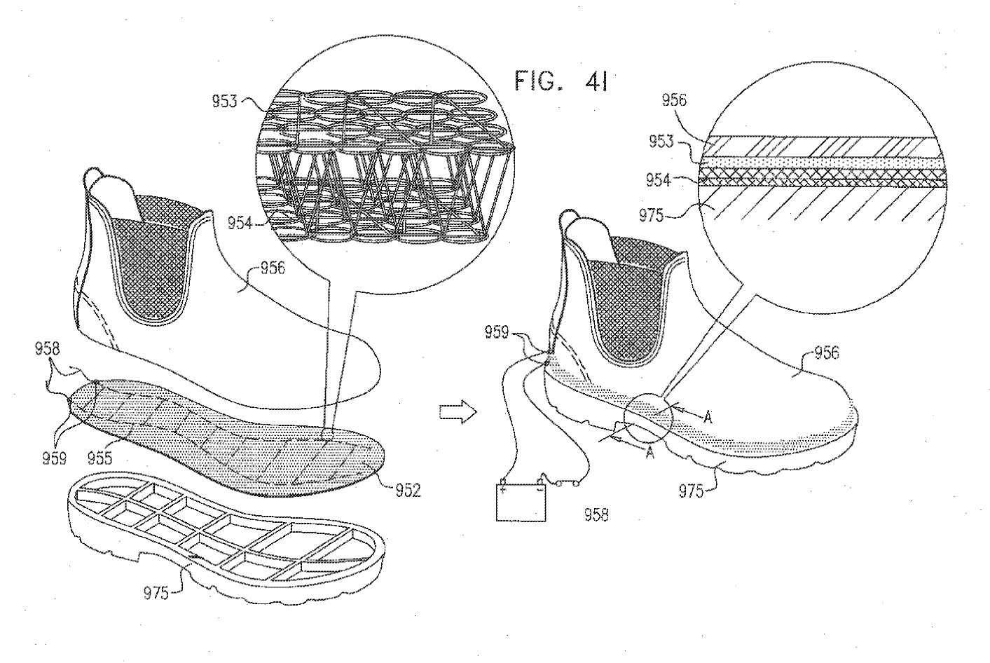

Reference is now made to FIGS. 4A, 4B, 4C, 4D, 4E, 4F, 4G, 4H & 4I, which are simplified pictorial illustrations of various modes of application of a web material in accordance with preferred embodiments of the present invention.

The web material is preferably formed in accordance with preferred embodiments of the present invention as described hereinabove, using conventional machinery for producing woven, knitted or felt fabrics.

Referring to FIG. 4A, there is seen an illustration of the manufacture of a glass-topped wooden table. Web material 872 constituting a two-sided adhesive fabric, preferably formed by double side knitting, is preferably made by knitting first and second adhesive fibers 873 and 874 together with electrical conductors 875.

The first fiber, 873 preferably is an adhesive fiber particularly suitable for bonding to wood, comprising, for example, Gorilla Glue™ commercially available from the Gorilla Glue Company of Cincinnati, Ohio.

The second fiber, 874 preferably is an adhesive fiber particularly suitable for bonding to glass, comprising, for example, DYMAX Light Weld® 429 glass adhesive, commercially available from DYMAX Corporation of Torrington, Conn.

It is a particular feature of the present invention that by knitting together the first and second fibers 873 and 874, the two fibers are mechanically joined and thus together produce an adhesive matrix which is particularly suitable for adhering wood and glass.

The web material 872 is placed over a wood surface 876 and a sheet of glass 877 is placed thereover. Preferably an electrical voltage is applied across electrical conductors 875, via connecting conductors 878 connected to terminals 879 of conductors 875 thereby to produce resistance heating thereof and consequent melting and activation of the adhesives. Once sufficient heating of conductors 875 is achieved, connecting conductors 878 may be removed. Conductors 875 and terminals 879 preferably remain in the adhesive. Should at a later time, it be desired to disengage the sheet of glass 877 from wood surface 876, this may be enabled by applying a suitable electrical voltage across conductors 875 at terminals 879.

Referring to FIG. 4B, there is seen an illustration of the manufacture of a chair including wooden armrests. Web material 882 constituting a two-sided adhesive fabric, preferably formed by double side knitting, is preferably made by knitting first and second adhesive fibers 883 and 884 together with electrical conductors 885.

The first fiber, 883 preferably is an adhesive fiber particularly suitable for bonding to steel, comprising, for example, a Polyaryl thermoplastic adhesive.

The second fiber, 884 preferably is an adhesive fiber particularly suitable for bonding to wood, comprising, for example, Gorilla Glue™ commercially available from the Gorilla Glue Company of Cincinnati, Ohio.

It is a particular feature of the present invention that by knitting together the first and second fibers 883 and 884, the two fibers are mechanically joined and thus together produce an adhesive matrix which is particularly suitable for adhering wood and steel.

The web material 882 is placed over a steel armrest support 886 and a wooden armrest 887 is placed thereover. Preferably an electrical voltage is applied across electrical conductors 885, via connecting conductors 888 connected to terminals 889 of conductors 885 thereby to produce resistance heating thereof and consequent melting and activation of the adhesives. Once sufficient heating of conductors 885 is achieved, connecting conductors 888 may be removed. Conductors 885 and terminals 889 preferably remain in the adhesive. Should at a later time, it be desired to disengage the wooden armrest 887 from steel armrest support 886, this may be enabled by applying a suitable electrical voltage across conductors 885 at terminals 889.

Referring to FIG. 4C, there is seen an illustration of the construction of a building including installing glass panes into a concrete frame. Web material 892 constituting a two-sided adhesive fabric, preferably formed by double side knitting, is preferably made by knitting first and second adhesive fibers 893 and 894 together with electrical conductors 895.

The first fiber, 893 preferably is an adhesive fiber particularly suitable for bonding to glass, comprising, for example, DYMAX Light Weld® 429 glass adhesive, commercially available from DYMAX Corporation of Torrington, Conn.

The second fiber, 894 preferably is an adhesive fiber particularly suitable for bonding to concrete, comprising, for example, RG+CONCRETE ADHESIVE, commercially available from Techniseal® of Candiac, Québec, Canada.

It is a particular feature of the present invention that by knitting together the first and second fibers 893 and 894, the two fibers are mechanically joined and thus together produce an adhesive matrix which is particularly suitable for adhering glass and concrete.

The web material 892 is placed over the outer perimeter of each pane of glass 896 before inserting the glass pane into the concrete frame 897. Preferably an electrical voltage is applied across electrical conductors 895, via connecting conductors 898 connected to terminals 899 of conductors 895 thereby to produce resistance heating thereof and consequent melting and activation of the adhesives. Once sufficient heating of conductors 895 is achieved, connecting conductors 898 may be removed. Conductors 895 and terminals 899 preferably remain in the adhesive. Should at a later time, it be desired to disengage any of the glass panes 896 from concrete frame 897, this may be enabled by applying a suitable electrical voltage across conductors 895 at terminals 899.

Referring to FIG. 4D, there is seen an illustration of the fastening of a plastic picture frame to a plasterboard wall. Web material 902 constituting a two-sided adhesive fabric, preferably formed by double side knitting, is preferably made by knitting first and second adhesive fibers 903 and 904 together with electrical conductors 905.

The first fiber, 903 preferably is an adhesive fiber particularly suitable for bonding to plastic, comprising, for example, 3M™ Plastic Bonding Adhesive 2665, commercially available from 3M™ of St. Paul, Minn..

The second fiber, 904 preferably is an adhesive fiber particularly suitable for bonding to plasterboard, comprising, for example, KSBOND, commercially available from Hangzhou Kuosen Chemical Industry Co., Ltd. of Hangzhou, China.

It is a particular feature of the present invention that by knitting together the first and second fibers 903 and 904, the two fibers are mechanically joined and thus together produce an adhesive matrix which is particularly suitable for adhering plastic and plasterboard.

The web material 902 is placed over the back of a plastic frame 906 which is temporarily fastened to and a plasterboard wall 907. Preferably an electrical voltage is applied across electrical conductors 905, via connecting conductors 908 connected to terminals 909 of conductors 905 thereby to produce resistance heating thereof and consequent melting and activation of the adhesives. Once sufficient heating of conductors 905 is achieved, connecting conductors 908 may be removed. Conductors 905 and terminals 909 preferably remain in the adhesive. Should at a later time, it be desired to disengage the plastic frame 906 from plasterboard wall 907, this may be enabled by applying a suitable electrical voltage across conductors 905 at terminals 909.

Referring to FIG. 4E, there is seen an illustration of the fastening of a plastic side bumper strip to an automobile. Web material 912 constituting a two-sided adhesive fabric, preferably formed by double side knitting, is preferably made by knitting first and second adhesive fibers 913 and 914 together with electrical conductors 915.

The first fiber, 913 preferably is an adhesive fiber particularly suitable for bonding to plastic, comprising, for example, 3M™ Plastic Bonding Adhesive 2665, commercially available from 3M™ of St. Paul, Minn.

The second fiber, 914 preferably is an adhesive fiber particularly suitable for bonding to steel, comprising, for example, a Polyaryl thermoplastic adhesive.

It is a particular feature of the present invention that by knitting together the first and second fibers 913 and 914, the two fibers are mechanically joined and thus together produce an adhesive matrix which is particularly suitable for adhering plastic and steel.

The web material 912 is placed over a plastic side bumper strip 916 and is temporarily fastened to the steel side of an automobile 917. Preferably an electrical voltage is applied across electrical conductors 915, via connecting conductors 918 connected to terminals 919 of conductors 915 thereby to produce resistance heating thereof and consequent melting and activation of the adhesives. Once sufficient heating of conductors 915 is achieved, connecting conductors 918 may be removed. Conductors 915 and terminals 919 preferably remain in the adhesive. Should at a later time, it be desired to disengage the plastic side bumper strip 916 from the side of automobile 917, this may be enabled by applying a suitable electrical voltage across conductors 915 at terminals 919.

Referring to FIG. 4F, there is seen an illustration of the fastening of a plurality of leather patches onto a nylon jacket. Web material 922 constituting a two-sided adhesive fabric, preferably formed by double side knitting, is preferably made by knitting first and second adhesive fibers 923 and 924 together with electrical conductors 925.

The first fiber, 923 preferably is an adhesive fiber particularly suitable for bonding to leather, comprising, for example, KSBOND, commercially available from Hangzhou Kuosen Chemical Industry Co., Ltd. of Hangzhou, China.

The second fiber, 924 preferably is an adhesive fiber particularly suitable for bonding to nylon, comprising, for example, KSBOND, commercially available from Hangzhou Kuosen Chemical Industry Co., Ltd. of Hangzhou, China.

It is a particular feature of the present invention that by knitting together the first and second fibers 923 and 924, the two fibers are mechanically joined and thus together produce an adhesive matrix which is particularly suitable for adhering leather and nylon.

The web material 922 is placed over each leather patch 926 and is temporarily fastened to the jacket 927. Preferably an electrical voltage is applied across electrical conductors 925, via connecting conductors 928 connected to terminals 929 of conductors 925 thereby to produce resistance heating thereof and consequent melting and activation of the adhesives. Once sufficient heating of conductors 925 is achieved, connecting conductors 928 may be removed. Conductors 925 and terminals 929 preferably remain in the adhesive. Should at a later time, it be desired to disengage one or more of the leather patches 926 from the jacket 927, this may be enabled by applying a suitable electrical voltage across conductors 925 at terminals 929.

Referring to FIG. 4G, there is seen an illustration of the adhesion of a carpet having a synthetic backing to concrete floor. Web material 932 constituting a two-sided adhesive fabric, preferably formed by double side knitting, is preferably made by knitting first and second adhesive fibers 933 and 934 together with electrical conductors 935.

The first fiber, 933 preferably is an adhesive fiber particularly suitable for bonding to plastic, comprising, for example, 3M™ Plastic Bonding Adhesive 2665, commercially available from 3M™ of St. Paul, Minn.

The second fiber, 934 preferably is an adhesive fiber particularly suitable for bonding to concrete, comprising, for example, RG+CONCRETE ADHESIVE, commercially available from Techniseal® of Candiac, Québec, Canada.

It is a particular feature of the present invention that by knitting together the first and second fibers 933 and 934, the two fibers are mechanically joined and thus together produce an adhesive matrix which is particularly suitable for adhering plastic and concrete.

The web material 932 is placed over the back of a carpet 936 which is placed over a concrete floor 937. Preferably an electrical voltage is applied across electrical conductors 935, via connecting conductors 938 connected to terminals 939 of conductors 935 thereby to produce resistance heating thereof and consequent melting and activation of the adhesives. Once sufficient heating of conductors 935 is achieved, connecting conductors 938 may be removed. Conductors 935 and terminals 939 preferably remain in the adhesive. Should at a later time, it be desired to disengage the carpet 936 from concrete floor 937, this may be enabled by applying a suitable electrical voltage across conductors 935 at terminals 939.

Referring to FIG. 4H, there is seen an illustration of the adhesion of a wallpaper to a concrete wall. Web material 942 constituting a two-sided adhesive fabric, preferably formed by double side knitting, is preferably made by knitting first and second adhesive fibers 943 and 944 together with electrical conductors 945.

The first fiber, 943 preferably is an adhesive fiber particularly suitable for bonding to paper, comprising, for example, KSBOND, commercially available from Hangzhou Kuosen Chemical Industry Co., Ltd. of Hangzhou, China.

The second fiber, 944 preferably is an adhesive fiber particularly suitable for bonding to concrete, comprising, for example, RG+CONCRETE ADHESIVE, commercially available from Techniseal® of Candiac, Québec, Canada.

It is a particular feature of the present invention that by knitting together the first and second fibers 943 and 944, the two fibers are mechanically joined and thus together produce an adhesive matrix which is particularly suitable for adhering paper and concrete.

The web material 942 is placed over the back of wallpaper 946 which is temporarily fastened onto wall 947. Preferably an electrical voltage is applied across electrical conductors 945, via connecting conductors 948 connected to terminals 949 of conductors 945 thereby to produce resistance heating thereof and consequent melting and activation of the adhesives. Once sufficient heating of conductors 945 is achieved, connecting conductors 948 may be removed. Conductors 945 and terminals 949 preferably remain in the adhesive. Should at a later time, it be desired to disengage the wallpaper 946 from concrete wall 947, this may be enabled by applying a suitable electrical voltage across conductors 945 at terminals 949.

Referring to FIG. 4I, there is seen an illustration of the adhering of a leather shoe body into a rubber shoe sole. Web material 952 constituting a two-sided adhesive fabric, preferably formed by double side knitting, is preferably made by knitting first and second adhesive fibers 953 and 954 together with electrical conductors 955.

The first fiber, 953 preferably is an adhesive fiber particularly suitable for bonding to leather, comprising, for example, KSBOND, commercially available from Hangzhou Kuosen Chemical Industry Co., Ltd. of Hangzhou, China.

The second fiber, 954 preferably is an adhesive fiber particularly suitable for bonding to rubber, comprising, for example, 3M™ Plastic Bonding Adhesive 2665, commercially available from 3M™ of St. Paul, Minn.

It is a particular feature of the present invention that by knitting together the first and second fibers 953 and 954, the two fibers are mechanically joined and thus together produce an adhesive matrix which is particularly suitable for adhering leather and rubber.

The web material 952 is placed over leather shoe body 956 and is placed over shoe sole 957. Preferably an electrical voltage is applied across electrical conductors 955, via connecting conductors 958 connected to terminals 959 of conductors 955 thereby to produce resistance heating thereof and consequent melting and activation of the adhesives. Once sufficient heating of conductors 955 is achieved, connecting conductors 958 may be removed. Conductors 955 and terminals 959 preferably remain in the adhesive. Should at a later time, it be desired to disengage the leather shoe body 956 from shoe sole 957, this may be enabled by applying a suitable electrical voltage across conductors 955 at terminals 959.

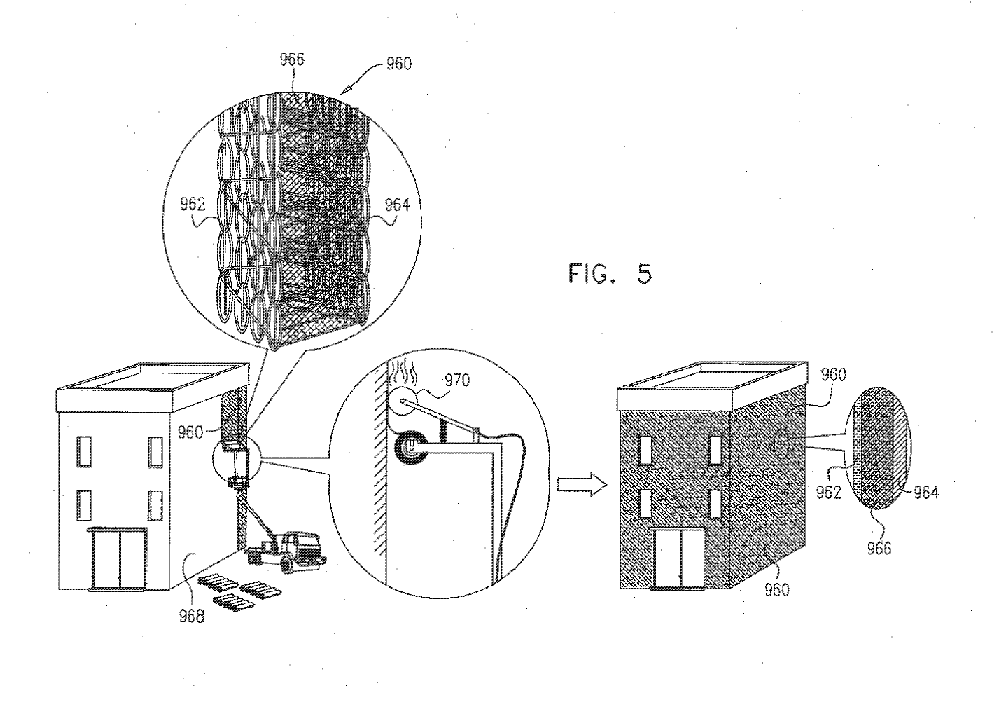

Reference is now made to FIG. 5, which is a simplified pictorial illustration of application of a web material in accordance with a preferred embodiment of the present invention. The web material is preferably formed in accordance with preferred embodiments of the present invention as described hereinabove, using conventional machinery for producing woven, knitted or felt fabrics.

As shown in FIG. 5, there is seen an illustration of the coating of an exterior wall of a building. Web material 960 constituting a two-sided fabric, preferably formed by double side knitting, is preferably made by knitting an adhesive fiber 962 and a paint fiber 964 together with a layer of insulating material 966.

The adhesive fiber, 962 preferably is an adhesive fiber particularly suitable for bonding to concrete, comprising, for example, RG+CONCRETE ADHESIVE, commercially available from Techniseal® of Candiac, Québec, Canada.

It is a particular feature of the present invention that by knitting together the fibers 962 and 964, the two fibers are mechanically joined and thus together produce an adhesive matrix which is particularly suitable for adhering the layer of insulating material 966 to an exterior concrete wall.

The web material 960 is simultaneously hung and heated on exterior concrete wall surface 968 as by a heated roller 970. Preferably, the temperature of the coating fabric 960 is raised to 300 degrees ° C., more preferably to 100° C. and most preferably to 80° C.

As illustrated in FIG. 5, heating of web material 960 on concrete wall surface 968 causes melting and activation of the adhesive and paint of web material 960, such that the fibers of web material 960 coalesce into an uninterrupted coating while adhering insulating material 966 to wall surface 968.

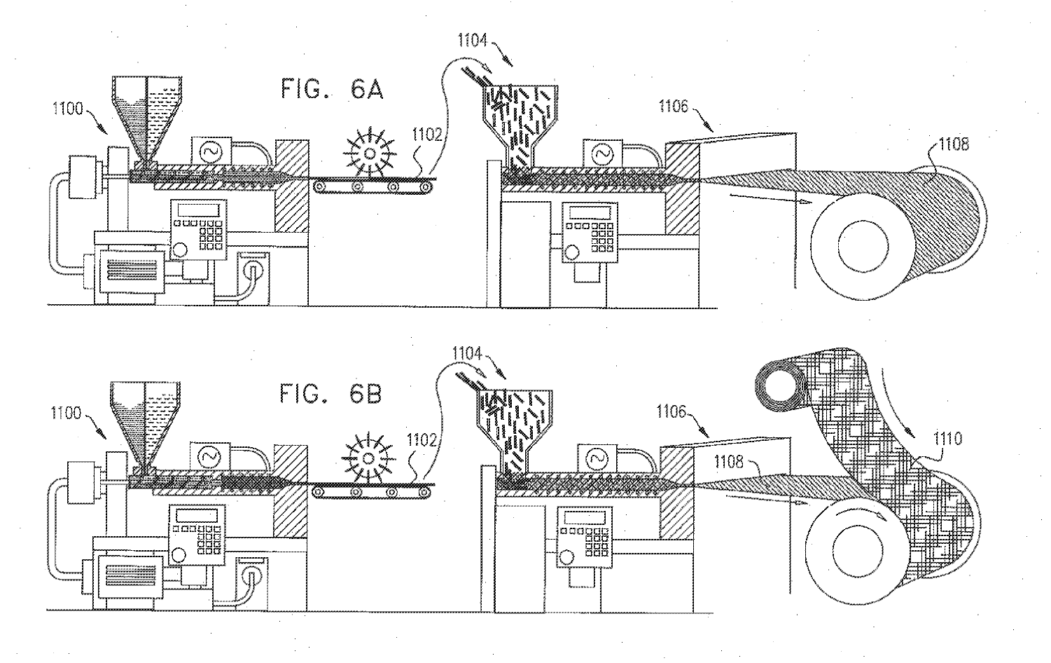

Reference is now made to FIGS. 6A and 6B, which are simplified pictorial illustrations of a process for producing meltable paint film in accordance with another preferred embodiment of the present invention. The meltable paint film of FIGS. 6A & 6B is characterized by having a first semi-adhesive solid state and a second adhesive solid state, which occurs subsequent to the film having passed through a non-solid state.

Preferably the film is formed of the following composition:
45% ethyl vinyl acetate 18% monomer;
30% HDPE and
24% hot melt adhesive pellets comprising:

ethyl vinyl acetate 9% monomer;

hydrogenated hydrocarbon tackifier resin; and

oil wax.

Hot melt adhesive pellets of the type specified above are commercially available from Devtec Technological Adhesives Ltd. of Petah Tikva, Israel, under the trade name KOMELT C-2285.

Additionally, one or more master batch pigments (20%) may be added to the composition to achieve coloring of the resulting paint film.

Alternatively, the film may be formed of the following composition:
30% LDPE 470;
30% master batch pigment;
15% anti block;
10% hot melt adhesive pellets comprising:

ethyl vinyl acetate 9% monomer;

hydrogenated hydrocarbon tackifier resin; and

oil wax;
2% paraffin wax; and
13% PSA C198 (3M).

Paraffin wax of the type specified above is commercially available from Tianjin Feilintake Chemical Co., Ltd. of Tianjin, China under the trade name of Kunlun 56/58.

Alternatively, other suitable compositions may be employed.

As seen in FIG. 6A, the above ingredients are preferably supplied to a double screw extruder 1100, such as a ZPT-HT Series Twin Screw Extruder, commercially available from ZENIX INDUSTRIAL CO. LTD. of Taoyuan, Taiwan, which mixes the above ingredients and extrudes a length of precursor material 1102. The precursor material 1102 is preferably pelletized downstream of the extruder and pellets 1104 of precursor material 1102 are supplied to a foam sheet extrusion line 1106, such as a FEX90120 Foam Sheet Extrusion Line, commercially available from SUNWELL GLOBAL LTD. of Hong Kong, which extrudes a meltable paint film 1108 in accordance with a preferred embodiment of the present invention.

Meltable paint film 1108 is preferably characterized in that it has both a tensile strength of at least 10 RKM, more preferably of at least 13.5 RKM and most preferably of at least 50 RKM, as well as an ultimate elongation of at most 20%, more preferably between 1% and 25% and most preferably at most 15%, a melting point preferably below 300° C., more preferably between 60° C. and 180° C. and most preferably no more than 100° C., adherence shear to steel (0.5 kg, min) of 130-300, peel adhesion to steel (N/25 mm) of 10-40, and a length per weight between 40 and 50 meters per gram.

Turning now to FIG. 6B, it is shown that release paper 1110 may be adhered to meltable paint film 1108 after meltable paint film 1108 is extruded from extruder 1106.

It is a particular feature of the present invention that meltable paint film 1108 is in a semi-adhesive solid state in which it can be temporarily adhered to a surface. Subsequent to activation, by which film 1108 is passed through a non-solid state, film 1108 is transformed to an adhesive solid state in which it is permanently melted onto the surface.

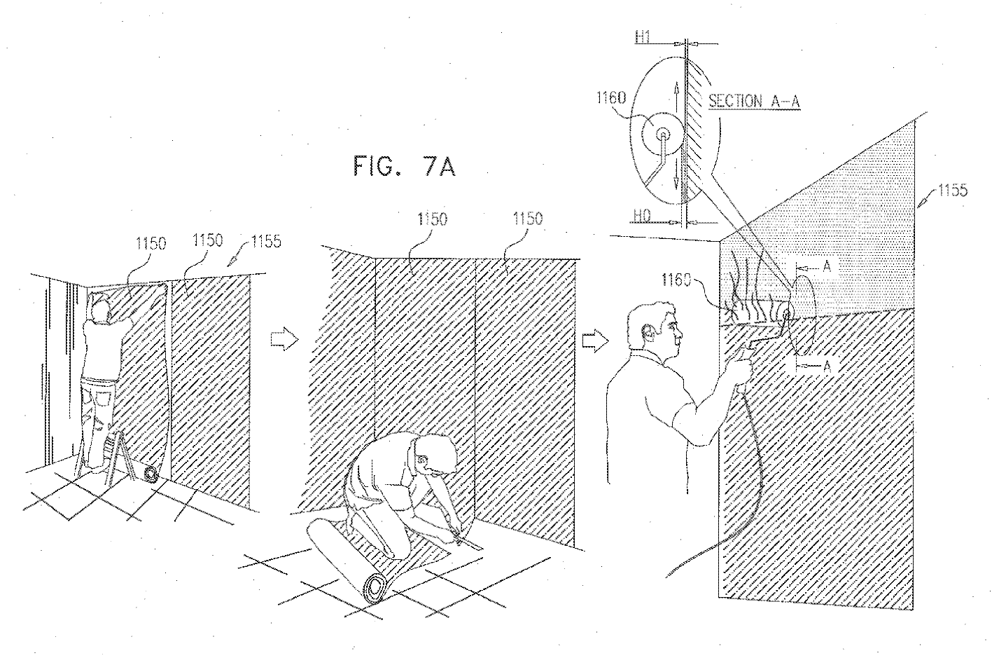

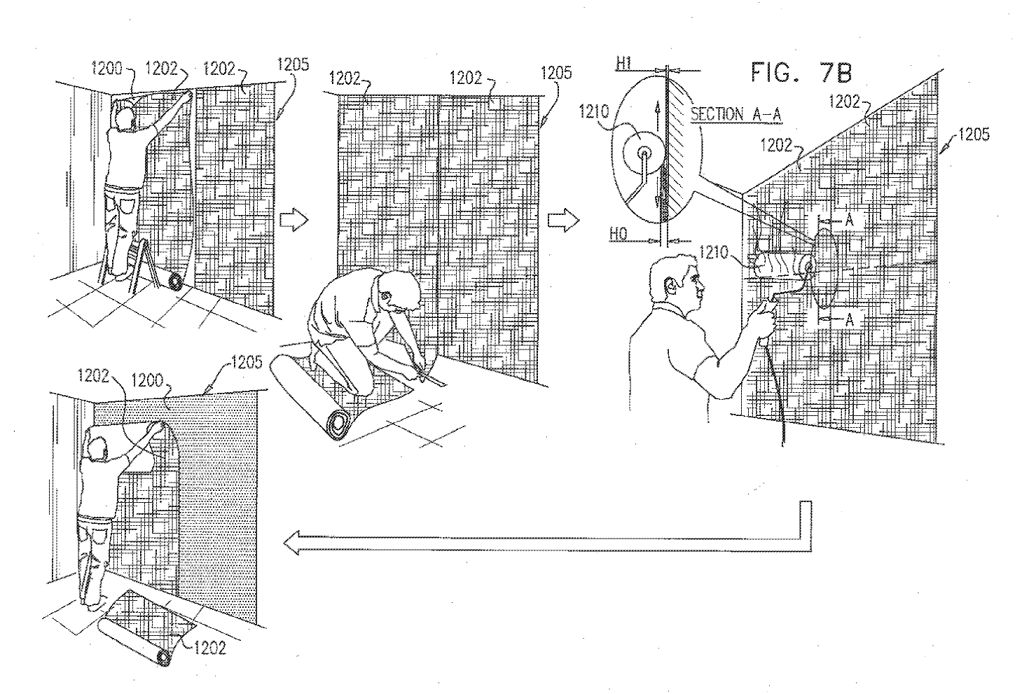

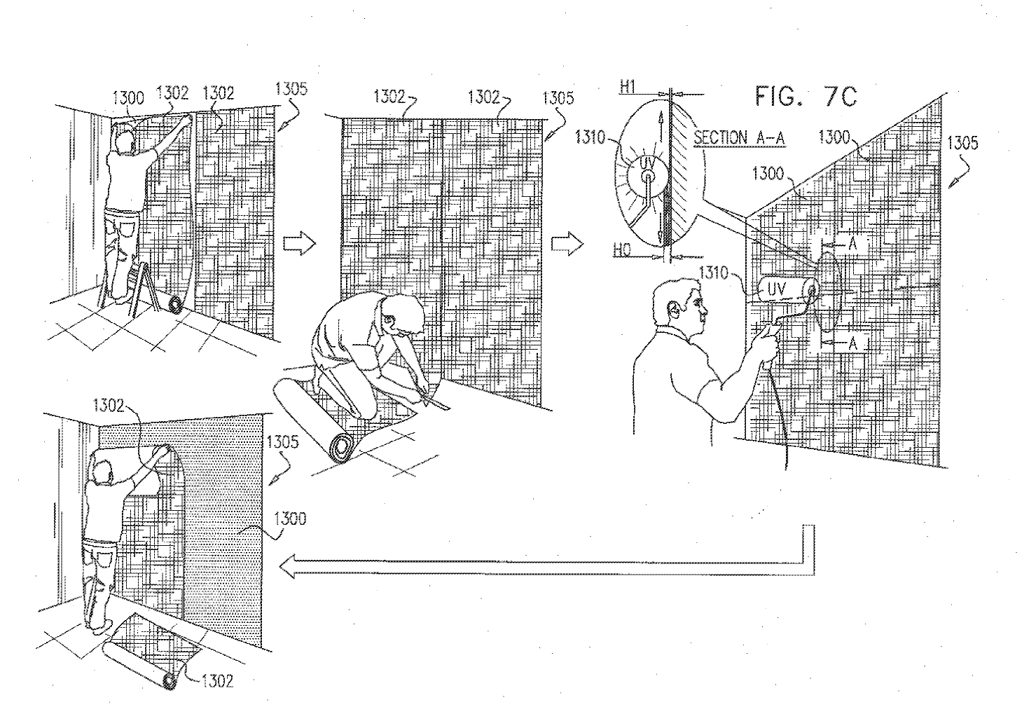

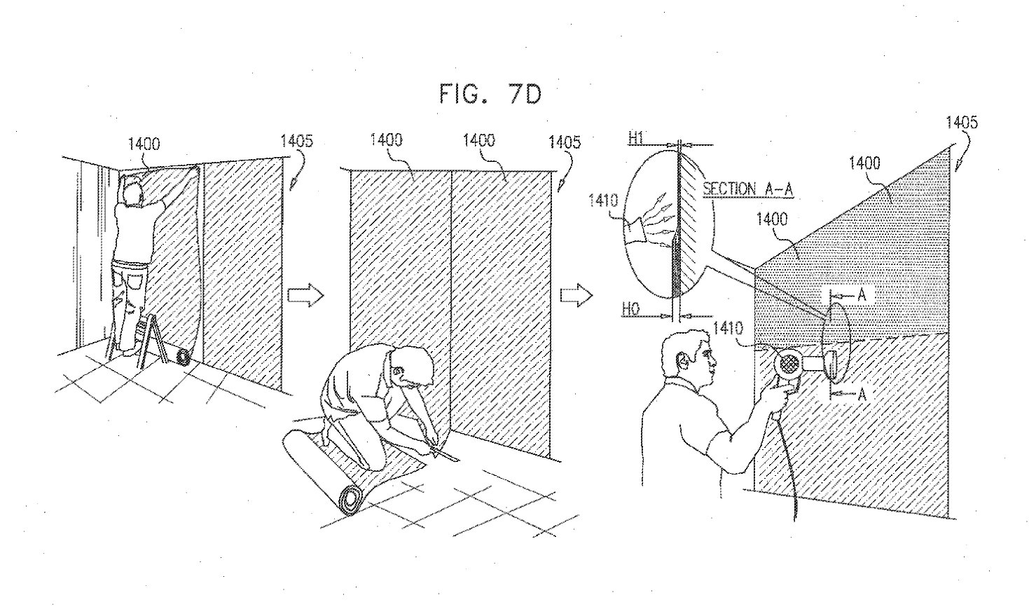

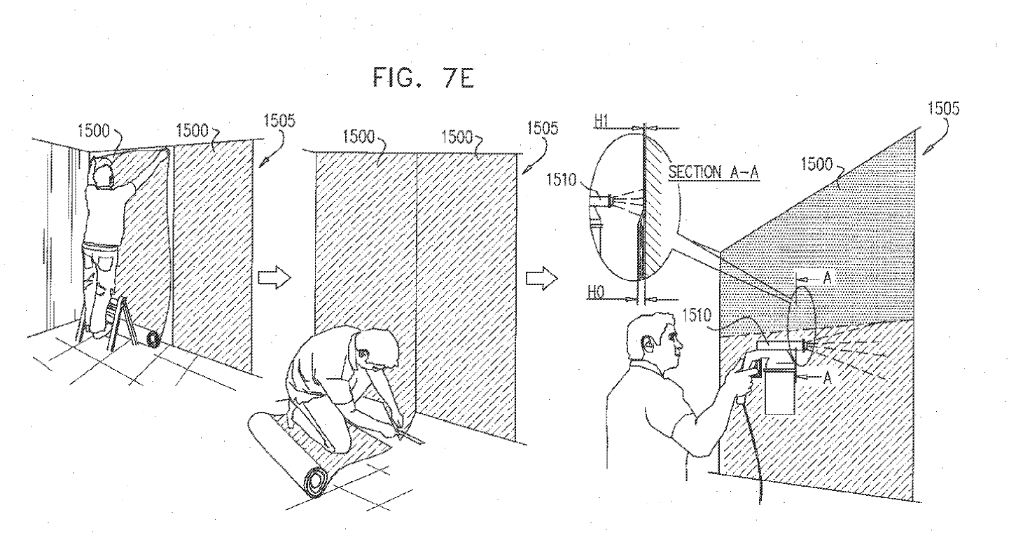

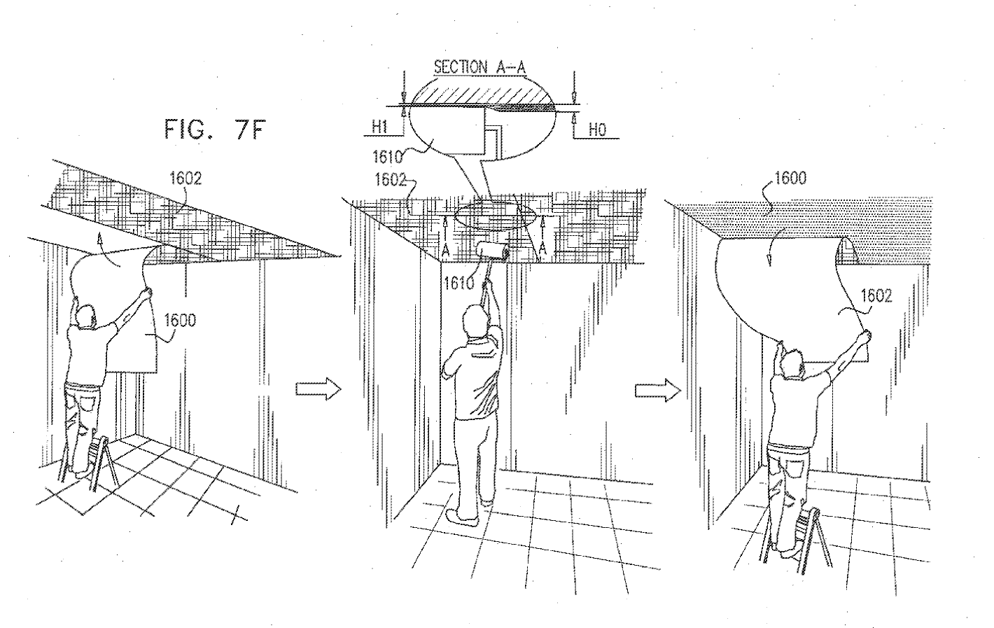

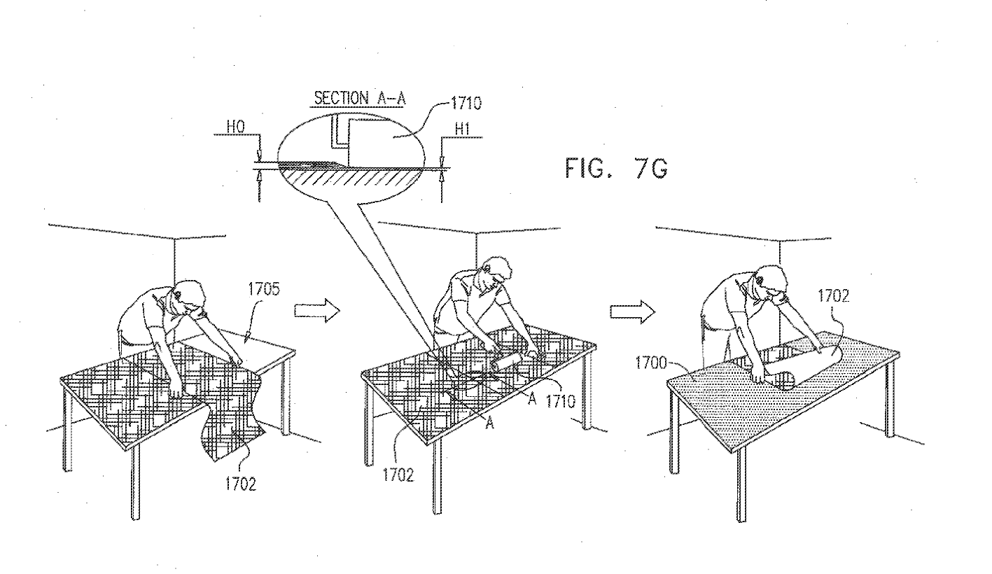

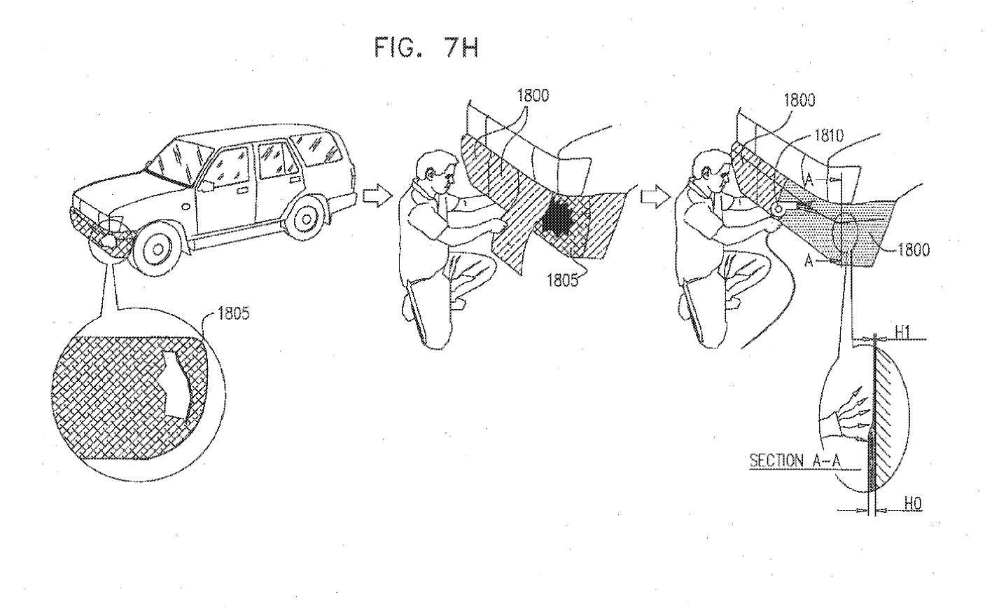

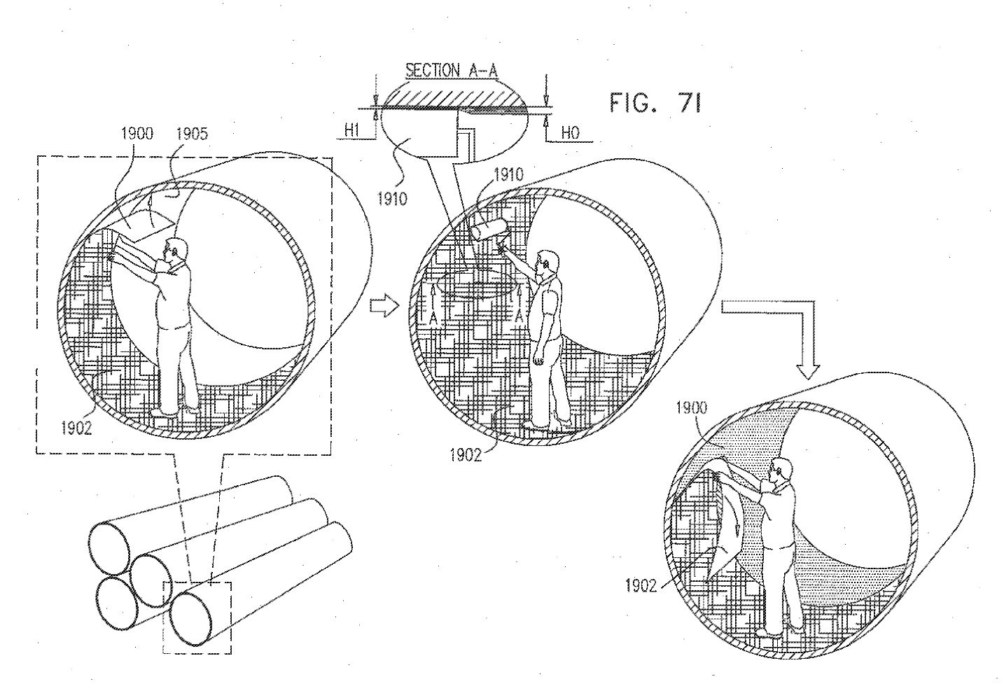

Reference is now made to FIGS. 7A, 7B, 7C, 7D, 7E, 7F, 7G, 7H and 7I, which are simplified pictorial illustrations of various modes of application of the meltable paint films of FIGS. 6A & 6B.

Referring now specifically to FIG. 7A, there is shown an example of application of meltable paint film to a vertical wall surface. As seen in FIG. 7A, strips of meltable paint film 1150 preferably produced as illustrated in FIG. 6A are temporarily adhered to a vertical wall surface 1155 and are cut to fit. Thereafter, meltable paint film 1150 is heated on wall surface 1155 by a heated roller 1160. Preferably, the temperature of meltable paint film 1150 is thereby raised to 300° C., more preferably to 160° C. and most preferably to 100° C. Normally, meltable paint film 1150 has a thickness of approximately 2 mm, more preferably 0.5 mm and most preferably 0.04 mm.

As illustrated in FIG. 7A, heating of meltable paint film 1150 on wall surface 1155 causes melting of meltable paint film 1150 and permanent adherence thereof to wall surface 1155, melted film 1150 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1150 prior to and following heating thereof, as designated by references H0 and H1, respectively.

Turning now to FIG. 7B, there is shown an example of application of meltable paint film to a vertical wall. As seen in FIG. 7B, strips of meltable paint film 1200 having release paper 1202 adhered thereto and preferably produced as illustrated in FIG. 6B are temporarily adhered to a wall surface 1205 and are cut to fit. Thereafter, meltable paint film 1200 is heated on wall surface 1205 by a heated roller 1210 which is applied to release paper 1202. It is appreciated that applying roller 1210 to release paper 1202 as illustrated in FIG. 7B is operative to prevent adherence of roller 1210 to meltable paint film 1200, and therefore may be preferable over the method illustrated in FIG. 7A wherein roller 1160 is applied directly to meltable paint film 1150.

Preferably, upon heating by roller 1210, the temperature of meltable paint film 1200 is raised to 300° C., more preferably to 160° C. and most preferably to 100° C. Normally, meltable paint film 1200 has a thickness of approximately 2 mm, more preferably 0.5 mm and most preferably 0.04 mm.

As illustrated in FIG. 7B, heating of meltable paint film 1200 on wall surface 1205 causes melting of meltable paint film 1200 and permanent adherence thereof to wall surface 1205, melted film 1200 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1200 prior to and following heating thereof, as designated by references H0 and H1, respectively.

Preferably, Subsequent to the permanent adherence of meltable paint film 1200 to wall surface 1205, release paper 1202 is readily detached from painted wall surface 1205.

Turning now to FIG. 7C, there is shown an example of application of meltable paint film to a vertical wall. As seen in FIG. 7C, strips of meltable paint film 1300 having release paper 1302 adhered thereto and preferably produced as illustrated in FIG. 6B are temporarily adhered to a wall surface 1305 and are cut to fit. Thereafter, meltable paint film 1300 is heated on wall surface 1305 by a UV roller 1310 which is applied to release paper 1302. It is appreciated that applying UV roller 1310 to release paper 1302 as illustrated in FIG. 7C is operative to prevent adherence of roller 1310 to meltable paint film 1300, and therefore may be preferable over the method illustrated in FIG. 7A wherein roller 1160 is applied directly to meltable paint film 1150.

Preferably, upon heating by UV roller 1310, the temperature of meltable paint film 1300 is raised to 300° C., more preferably to 160° C. and most preferably to 100° C. Normally, meltable paint film 1300 has a thickness of approximately 2 mm, more preferably 0.5 mm and most preferably 0.04 mm.

As illustrated in FIG. 7C, heating of meltable paint film 1300 on wall surface 1305 causes melting of meltable paint film 1300 and permanent adherence thereof to wall surface 1305, melted film 1300 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1300 prior to and following heating thereof, as designated by references H0 and H1, respectively.

Subsequent to the permanent adherence of meltable paint film 1300 to wall surface 1305, release paper 1302 is readily detached from painted wall surface 1305.

Turning now to FIG. 7D, there is shown an example of application of meltable paint film to a vertical wall. As seen in FIG. 7D, strips of meltable paint film 1400 preferably produced as illustrated in FIG. 6A are temporarily adhered to a wall surface 1405 and are cut to fit. Thereafter, meltable paint film 1400 is heated on wall surface 1405 in a non-contact manner by a blow heater 1410.

Preferably, upon heating by blow heater 1410 the temperature of meltable paint film 1400 is raised to 300° C., more preferably to 160° C. and most preferably to 100° C. Normally, meltable paint film 1400 has a thickness of approximately 2 mm, more preferably 0.5 mm and most preferably 0.04 mm.

As illustrated in FIG. 7D, heating of meltable paint film 1400 on wall surface 1405 causes melting of meltable paint film 1400 and permanent adherence thereof to wall surface 1405, melted film 1400 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1400 prior to and following heating thereof, as designated by references H0 and H1, respectively.

Turning now to FIG. 7E, there is shown an example of application of meltable paint film to a vertical wall. As seen in FIG. 7E, strips of meltable paint film 1500, preferably produced as illustrated in FIG. 6A, are temporarily adhered to a wall surface 1505 and are cut to fit. Thereafter, meltable paint film 1500 is caused to assume a liquid-like phase on wall surface 1505 upon application thereto of a suitable solvent, such as petroleum distillate. Subsequently, meltable paint film 1500 assumes a solid phase, melted onto wall surface 1505.

Normally, meltable paint film 1500 has a thickness of approximately 2 mm, more preferably 0.5 mm and most preferably 0.04 mm.

As illustrated in FIG. 7E, melting of meltable paint film 1500 onto wall surface 1505 causes permanent adherence thereof to wall surface 1505, melted film 1500 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1500 prior to and following melting thereof, as designated by references H0 and H1, respectively.

Turning now to FIG. 7F, there is shown an example of application of meltable paint film to a ceiling. As seen in FIG. 7F, strips of meltable paint film 1600 having release paper 1602 adhered thereto and preferably produced as illustrated in FIG. 6B are temporarily adhered to a ceiling 1605 and are cut to fit. Thereafter, meltable paint film 1600 is heated on ceiling 1605 by a heated roller 1610 which is applied to release paper 1602. It is appreciated that applying roller 1610 to release paper 1602 as illustrated in FIG. 7F is operative to prevent adherence of roller 1610 to meltable paint film 1600.

Preferably, upon heating by roller 1610 the temperature of meltable paint film 1600 is raised to 300° C., more preferably to 160° C. and most preferably to 100° C. Normally, meltable paint film 1600 has a thickness of approximately 2 mm, more preferably 0.5 mm and most preferably 0.04 mm.

As illustrated in FIG. 7F, heating of meltable paint film 1600 on ceiling 1605 causes melting of meltable paint film 1600 and permanent adherence thereof to ceiling 1605, melted film 1600 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1600 prior to and following heating thereof, as designated by references H0 and H1, respectively.

Subsequent to the permanent adherence of meltable paint film 1600 to ceiling 1605, release paper 1602 is readily detached from painted ceiling 1605.

Turning now to FIG. 7G, there is shown an example of application of meltable paint film to a horizontal furniture surface such as a table. As seen in FIG. 7G, strips of meltable paint film 1700 having release paper 1702 adhered thereto and preferably produced as illustrated in FIG. 6B are temporarily adhered to a horizontal table surface 1705 and are cut to fit. Thereafter, meltable paint film 1700 is heated on surface 1705 by a heated roller 1710 which is applied to release paper 1702. It is appreciated that applying roller 1710 to release paper 1702 as illustrated in FIG. 7G is operative to prevent adherence of roller 1710 to meltable paint film 1700.

Preferably, upon heating by roller 1710 the temperature of meltable paint film 1700 is raised to 300° C., more preferably to 160° C. and most preferably to 100° C. Normally, meltable paint film 1700 has a thickness of approximately 2 mm, more preferably 0.5 mm and most preferably 0.04 mm.

As illustrated in FIG. 7G, heating of meltable paint film 1700 on surface 1705 causes melting of meltable paint film 1700 and permanent adherence thereof to surface 1705, melted film 1700 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1700 prior to and following heating thereof, as designated by references H0 and H1, respectively.

Subsequent to the permanent adherence of meltable paint film 1700 to surface 1705, release paper 1702 is readily detached from painted surface 1705.

Turning now to FIG. 7H, there is shown an example of application of meltable paint film to a vehicle surface such as a bumper. As seen in FIG. 7H, strips of meltable paint film 1800 preferably produced as illustrated in FIG. 6A are temporarily adhered to a bumper surface 1805 and are cut to fit. Thereafter, meltable paint film 1800 is heated on surface 1805 in a non-contact manner by a blow heater 1810.

Preferably, upon heating by blow heater 1810 the temperature of meltable paint film 1800 is raised to 300° C., more preferably to 160° C. and most preferably to 100° C. Normally, meltable paint film 1800 has a thickness of approximately 2 mm, more preferably 0.5 mm and most preferably 0.04 mm.

As illustrated in FIG. 7H, heating of meltable paint film 1800 on surface 1805 causes melting of meltable paint film 1800 and permanent adherence thereof to wall surface 1805, melted film 1800 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1800 prior to and following heating thereof, as designated by references H0 and H1, respectively.

Turning now to FIG. 7I, there is shown an example of application of meltable paint film to an interior surface of a horizontal pipe. As seen in FIG. 7I, strips of meltable paint film 1900 having release paper 1902 adhered thereto and preferably produced as illustrated in FIG. 6B are temporarily adhered to an interior surface of a horizontal pipe 1905 and are cut to fit. Thereafter, meltable paint film 1900 is heated on surface 1905 by a heated roller 1910 which is applied to release paper 1902. It is appreciated that applying roller 1910 to release paper 1902 as illustrated in FIG. 7I is operative to prevent adherence of roller 1910 to meltable paint film 1900, and is therefore preferable over the method illustrated in FIG. 7A wherein roller 1160 is applied directly to meltable paint film 1150.

Preferably, upon heating by roller 1910 the temperature of meltable paint film 1900 is raised to 300° C., more preferably to 160° C. and most preferably to 100° C.

Normally, meltable paint film 1900 has a thickness of approximately 2 mm, more preferably 0.5 mm and most preferably 0.04 mm.

As illustrated in FIG. 7I, heating of meltable paint film 1900 on surface 1905 causes melting of meltable paint film 1900 and permanent adherence thereof to surface 1905, melted film 1900 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 1900 prior to and following heating thereof, as designated by references H0 and H1, respectively.

Subsequent to the permanent adherence of meltable paint film 1900 to surface 1905, release paper 1902 is readily detached from painted wall surface 1905.

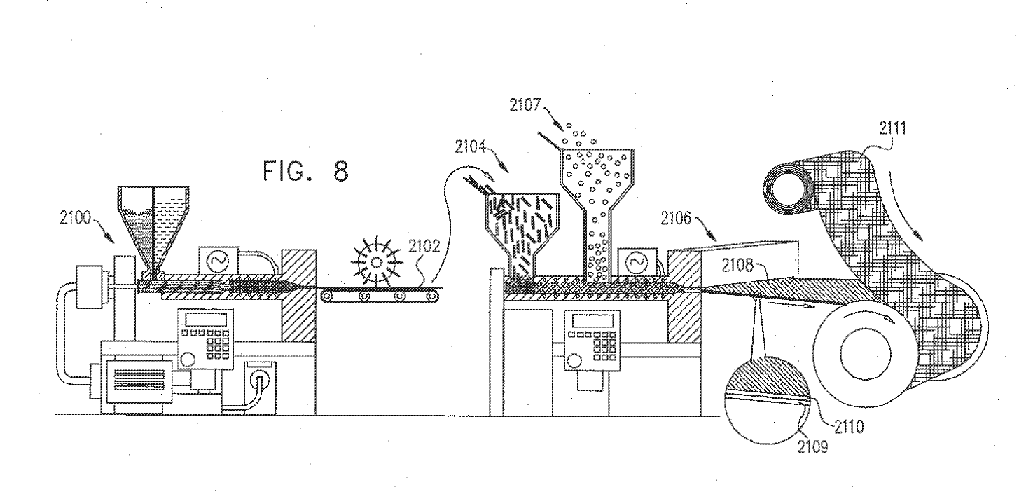

Reference is now made to FIG. 8, which is a simplified pictorial illustrations of a process for producing polymer-coated meltable paint film in accordance with yet another preferred embodiment of the present invention. The polymer-coated meltable paint film of FIG. 8 is characterized by having a first semi-adhesive solid state and a second adhesive solid state, which occurs subsequent to the film having passed through a non-solid state.

Preferably the film is formed of the following composition:
45% ethyl vinyl acetate 18% monomer;
30% HDPE and
24% hot melt adhesive pellets comprising:

ethyl vinyl acetate 9% monomer;

hydrogenated hydrocarbon tackifier resin; and

oil wax.

Hot melt adhesive pellets of the type specified above are commercially available from Devtec Technological Adhesives Ltd. of Petah Tikva, Israel, under the trade name KOMELT C-2285.

Additionally, one or more master batch pigments (20%) may be added to the composition to achieve coloring of the resulting paint film.

Alternatively, the film may be formed of the following composition:
30% LDPE 470;
30% master batch pigment;
15% anti block;
10% hot melt adhesive pellets comprising:

ethyl vinyl acetate 9% monomer;

hydrogenated hydrocarbon tackifier resin; and

oil wax;
2% paraffin wax; and
13% PSA C198 (3M).

Paraffin wax of the type specified above is commercially available from Tianjin Feilintake Chemical Co., Ltd. of Tianjin, China under the trade name of Kunlun 56/58.

Alternatively, other suitable compositions may be employed.

As seen in FIG. 8, the above ingredients are preferably supplied to a double screw extruder 2100, such as a ZPT-HT Series Twin Screw Extruder, commercially available from ZENIX INDUSTRIAL CO. LTD. of Taoyuan, Taiwan, which mixes the above ingredients and extrudes a length of precursor material 2102. The precursor material 2102 is preferably pelletized downstream of the extruder and pellets 2104 of precursor material 2102 are provided to a foam sheet extrusion line 2106, such as a FEX90120 Foam Sheet Extrusion Line, commercially available from SUNWELL GLOBAL LTD. of Hong Kong. Preferably, pellets 2107 of a polymeric material such as LLDPE are also provided to foam sheet extrusion line 2106, which extrudes a polymer-coated meltable paint film 2108. In accordance with this embodiment of the present invention, polymer-coated meltable paint film 2108 comprises a lower paint film layer 2109 and an upper polymeric layer 2110.

Polymer-coated meltable paint film 2108 is preferably characterized in that it has both a tensile strength of at least 10 RKM, more preferably of at least 13.5 RKM and most preferably of at least 50 RKM, as well as an ultimate elongation of at most 20%, more preferably between 1% and 25% and most preferably at most 15%, a melting point preferably below 300° C., more preferably between 60° C. and 180° C. and most preferably no more than 100° C., adherence shear to steel (0.5 kg, min) of 130-300, peel adhesion to steel (N/25 mm) of 10-40, and a length per weight between 40 and 50 meters per gram.

As also shown in FIG. 8, release paper 2111 is preferably adhered to polymer-coated meltable paint film 2108 after polymer-coated meltable paint film 2108 is extruded from extruder 2106.

It is a particular feature of the present invention that polymer-coated meltable paint film 2108 is in a semi-adhesive solid state in which it can be temporarily adhered to a surface. Subsequent to activation, by which film 2108 is passed through a non-solid state, film 2108 is transformed to an adhesive solid state in which it is permanently melted onto the surface.

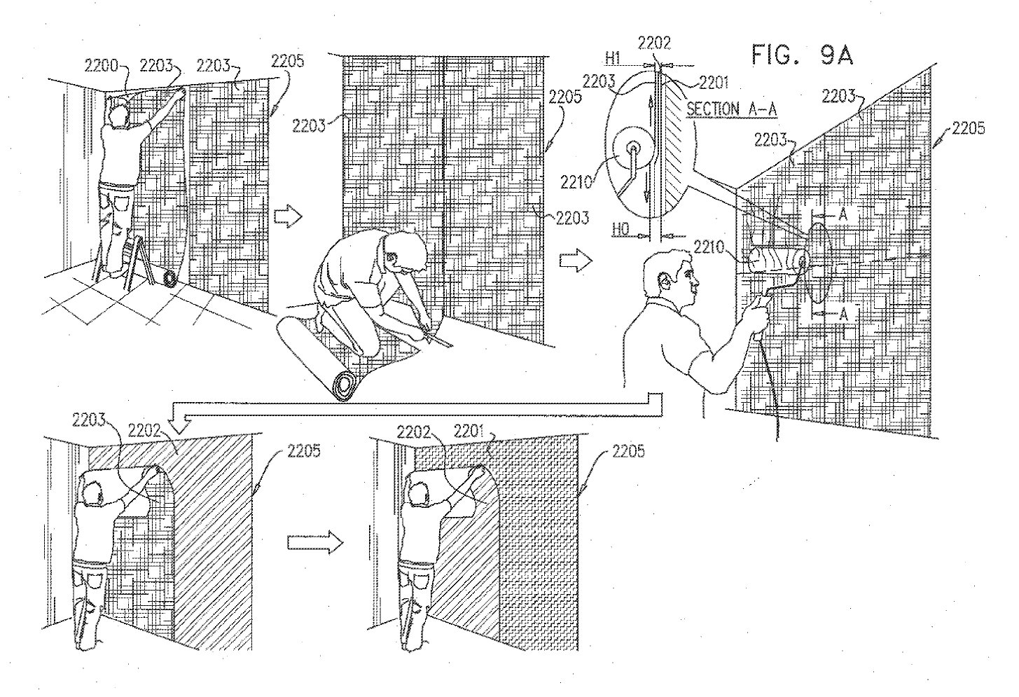

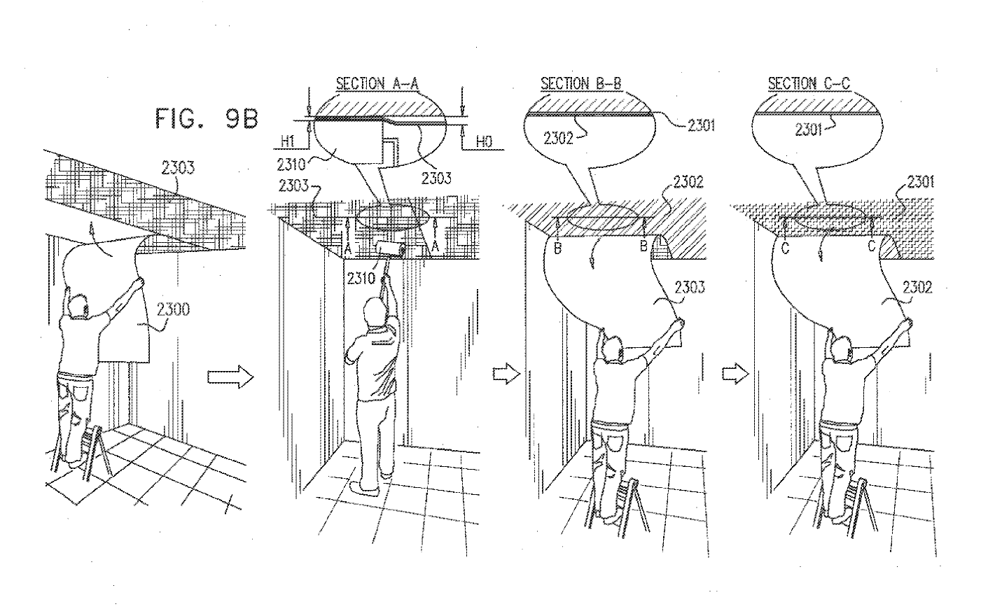

Reference is now made to FIGS. 9A and 9B, which are simplified pictorial illustrations of various modes of application of the polymer-coated meltable paint film of FIG. 8. Referring first specifically to FIG. 9A, there is shown an example of application of polymer-coated meltable paint film to a vertical wall. As seen in FIG. 9A, strips of polymer-coated meltable paint film 2200, comprising a paint film layer 2201 and a polymeric layer 2202 with release paper 2203 adhered thereto, and which are preferably produced as illustrated in FIG. 8 are temporarily adhered to a wall surface 2205 and are cut to fit. Thereafter, polymer-coated meltable paint film 2200 is heated on wall surface 2205 by a heated roller 2210 which is applied to release paper 2203. It is appreciated that applying roller 2210 to release paper 2203 as illustrated in FIG. 9A is operative to prevent adherence of roller 2210 to polymer-coated meltable paint film 2200.

Preferably, upon heating by roller 2210, the temperature of polymer-coated meltable paint film 2200 is raised to 300° C., more preferably to 160° C. and most preferably to 100° C. Normally, paint film layer 2201 of polymer-coated meltable paint film 2200 has a thickness of approximately 2 mm, more preferably 0.5 mm and most preferably 0.04 mm.

As illustrated in FIG. 9A, heating of polymer-coated meltable paint film 2200 on wall surface 2205 causes melting of paint film layer 2201 meltable paint film 2200 and permanent adherence thereof to wall surface 2205, melted paint film layer 2201 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 2200 prior to and following heating thereof, as designated by references H0 and H1, respectively.

Preferably, subsequent to the permanent adherence of meltable paint film 2200 to wall surface 2205, release paper 2202 is readily detached from polymeric layer 2202. Thereafter, polymeric layer 2202 is readily detached from the painted wall surface 2205. It is appreciated that polymeric layer 2202 is operative to prevent overheating of paint film layer 2101 during application of heated roller 2210, and is thereby operative to achieve a generally smooth and even spread of the paint in paint film layer 2201 on wall surface 2205.

Turning now to FIG. 9B, there is shown an example of application of polymer-coated meltable paint film to a ceiling. As seen in FIG. 9B, strips of polymer-coated meltable paint film 2300, comprising a paint film layer 2301 and a polymeric layer 2302 with release paper 2303 adhered thereto, and which are preferably produced as illustrated in FIG. 8 are temporarily adhered to a ceiling 2305 and are cut to fit. Thereafter, polymer-coated meltable paint film 2300 is heated on ceiling 2305 by a heated roller 2310 which is applied to release paper 2303. It is appreciated that applying roller 2310 to release paper 2303 as illustrated in FIG. 9B is operative to prevent adherence of roller 2310 to polymer-coated meltable paint film 2300.

Preferably, upon heating by roller 2310, the temperature of polymer-coated meltable paint film 2300 is raised to 300° C., more preferably to 160° C. and most preferably to 100° C. Normally, paint film layer 2301 of polymer-coated meltable paint film 2200 has a thickness of approximately 2 mm, more preferably 0.5 mm and most preferably 0.04 mm.

As illustrated in FIG. 9B, heating of polymer-coated meltable paint film 2300 on ceiling 2305 causes melting of paint film layer 2301 meltable paint film 2300 and permanent adherence thereof to ceiling 2305, melted paint film layer 2301 preferably having a thickness which is less than 60% of its earlier thickness, more preferably less than 50% of its earlier thickness and most preferably less than 40% of its earlier thickness. This is illustrated with clarity at section A, which shows the difference in thickness in meltable paint film 2300 prior to and following heating thereof, as designated by references H0 and H1, respectively.

Preferably, subsequent to the permanent adherence of meltable paint film 2300 to ceiling 2305, release paper 2302 is readily detached from polymeric layer 2302. Thereafter, polymeric layer 2302 is readily detached from the painted ceiling 2305. It is appreciated that polymeric layer 2302 is operative to prevent overheating of paint film layer 2301 during application of heated roller 2310, and is thereby operative to achieve a generally smooth and even spread of the paint in paint film layer 2301 on ceiling 2305.

It will be appreciated by persons skilled in the art that the present invention is not limited by what has been particularly shown and described hereinabove. Rather the scope of the present invention includes both combinations and subcombinations of the various features described hereinabove as well as modifications thereof which would occur to persons skilled in the art upon reading the foregoing description and which are not in the prior art.

1. A fabric which is formed of fibers joined together by at least one of knitting, weaving and felting techniques, which is characterized by having a first non-adhesive solid state and a second adhesive solid state, which occurs subsequent to having passed through an adhesive non-solid state.

2. A fabric according to claim 1 and wherein said fibers are formed of a material characterized by having said first non-adhesive solid state and said second adhesive solid state, which occurs subsequent to having passed through an adhesive non-solid state.

3. A fabric according to claim 1 and wherein said fibers include first and second different fibers which are characterized in that they assume said adhesive non-solid state when they are together subject to predetermined activation conditions.

4. A fabric according to claim 3 and wherein said predetermined activation conditions include application of at least one of pressure, heat, ultraviolet radiation, electricity and a solvent.

5. A fabric according to claim 4 and wherein said solvent comprises petroleum distillate.

6. A fabric according to claim 4 and wherein said fabric also includes an array of electrical conductors which when connected to a source of electrical energy produce said activation of said fabric.

7. A fabric according to claim 1 and wherein said fabric also includes acoustic insulating material joined to said fibers by at least one of interknitting and interweaving.

8. A fabric according to claim 1 and wherein said fabric also includes thermal insulating material joined to said fibers by at least one of interknitting and interweaving.

9. A fabric which is formed of fibers joined together by at least one of knitting, weaving and felting techniques, which is characterized by having a first thickness in a first solid state and a second thickness in a second solid state subsequent to having passed through a non-solid state, said second thickness being less than 60% of said first thickness.

10. A fabric according to claim 9 and wherein said second thickness is less than 50% of said first thickness.

11. A fabric according to claim 9 and wherein said second thickness is less than 40% of said first thickness.

12. A fabric according to claim 9 and wherein said second thickness is less than 10% of said first thickness.

13. A fabric according to claim 9 and wherein said fabric is further characterized in having adhesive properties in said second solid state but not in said first solid state.

14. A fabric according to claim 9 and wherein said fibers are characterized in that they assume said non-solid state when they are subject to predetermined activation conditions.

15. A fabric according to claim 14 and wherein said predetermined activation conditions include application of at least one of pressure, heat, ultraviolet radiation, electricity and a solvent.

16. A fabric according to claim 15 and wherein said solvent comprises petroleum distillate.

17. A fabric according to claim 15 and wherein said fabric also includes an array of electrical conductors which when connected to a source of electrical energy produce said activation of said fabric.

18. A fabric according to claim 9 and wherein said fabric also includes acoustic insulating material joined to said fibers by at least one of interknitting and interweaving.

19. A fabric according to claim 9 and wherein said fabric also includes thermal insulating material joined to said fibers by at least one of interknitting and interweaving.

20. A fiber having adhesive properties following activation thereof, comprising approximately:
45% Ethyl vinyl acetate 18% monomer;
30% HDPE; and
24% hot melt adhesive pellets comprising:
Ethyl vinyl acetate 9% monomer;
Hydrogenated hydrocarbon tackifier resin; and
Oil wax;
and generally having the following characteristics:
a tensile strength of at least 50 RKM;
an ultimate elongation of at most 15%;
a melting point of less than 80° C.;
an adherence shear to steel (0.5 kg, min) between 130 and 300;
a peel adhesion to steel (N/25 mm) between 10 and 40; and
a length per weight between 40 and 50 meters per gram.

21-220. (canceled)
